(19) United States
(12) Patent Application Publication
(10) Pub. No.: US 2025/0070024 A1
(43) Pub. Date: Feb. 27, 2025

(54) SEMICONDUCTOR MEMORY DEVICE

(71) Applicant: Kioxia Corporation, Tokyo (JP)

(72) Inventors: Takafumi MASUDA, Kawasaki Kanagawa (JP); Mutsumi OKAJIMA, Yokkaichi Mie (JP); Nobuyoshi SAITO, Ota Tokyo (JP); Keiji IKEDA, Kawasaki Kanagawa (JP)

(21) Appl. No.: 18/811,335

(22) Filed: Aug. 21, 2024

(30) Foreign Application Priority Data
Aug. 22, 2023 (JP) 2023-134511

(51) Int. Cl. H01L 23/528; H01L 23/522; H10B 53/10; H10B 53/20

(52) U.S. Cl. CPC H01L 23/5283; H01L 23/5226; H10B 53/10; H10B 53/20

(57) ABSTRACT

A semiconductor memory device includes a substrate, first semiconductor layers stacked in a first direction intersecting the substrate, a first via wiring extending in the direction and connected to the layers, memory units stacked in the direction and connected to the layers, first gate electrodes stacked in the direction and facing the layers, first wirings stacked in the direction, extending in a second direction intersecting the first direction, and connected to the first electrodes, second semiconductor layers stacked in the first direction and connected to the first electrodes via the first wirings, a second via wiring extending in the first direction and connected to the second layers, and second gate electrodes stacked in the first direction and facing the second layers. The second layers include a different material from the first layers, or a composition ratio of materials of the second layers is different from that of the first layers.

### CROSS-REFERENCE TO RELATED APPLICATIONS

This application is based upon and claims the benefit of priority from Japanese Patent Application No. 2023-134511, filed Aug. 22, 2023, the entire contents of which are incorporated herein by reference.

### FIELD

Embodiments described herein relate generally to a semiconductor memory device.

### BACKGROUND

As semiconductor memory devices become more highly integrated, advancements have been made in three-dimensional semiconductor memory devices.

### BRIEF DESCRIPTION OF THE DRAWINGS

FIG. 1 is a schematic circuit diagram illustrating the configuration of a semiconductor memory device according to a first embodiment.

FIG. 2 is a schematic circuit diagram for describing a read operation of the semiconductor memory device.

FIG. 3 is a graph illustrating the magnitude relationship of the voltages applied to a word line WL and a layer selection line LL in the read operation.

FIG. 4 is a schematic perspective view illustrating the configuration of a part of the semiconductor memory device according to the first embodiment.

FIG. 5 is a schematic XY cross-sectional view illustrating the configuration of a part of a memory layer ML.

FIG. 6 is a schematic XY cross-sectional view illustrating the configuration of a part of the memory layer ML.

FIG. 7 illustrates a cross section of a structure illustrated in FIG. 6 taken along A-A′ line.

FIG. 8 is a schematic XY cross-sectional view illustrating the configuration of a part of the memory layer ML.

FIG. 9 illustrates a cross section of a structure illustrated in FIG. 8 taken along B-B′ line.

FIG. 10 is a schematic cross-sectional view illustrating the configuration of the semiconductor memory device according to the first embodiment.

FIG. 11 is a schematic cross-sectional view for describing a manufacturing method of the semiconductor memory device.

FIGS. 12-77 are schematic cross-sectional views for describing the manufacturing method.

FIG. 78 is a schematic cross-sectional view illustrating the configuration of a part of a semiconductor memory device according to a second embodiment.

FIG. 79 is a schematic cross-sectional view for describing a manufacturing method of the semiconductor memory device according to the second embodiment.

FIGS. 80-84 are schematic cross-sectional views for describing the manufacturing method.

FIGS. 85 and 86 are schematic cross-sectional views illustrating the configuration of a part of a semiconductor memory device according to a third embodiment.

FIGS. 87 and 88 are schematic cross-sectional views for describing a manufacturing method of the semiconductor memory device according to the third embodiment.

FIGS. 89 and 90 are schematic cross-sectional views illustrating the configuration of a part of a semiconductor memory device according to a fourth embodiment.

FIGS. 91 and 92 are schematic cross-sectional views illustrating the configuration of a part of a semiconductor memory device according to a fifth embodiment.

FIG. 93 is a schematic cross-sectional view illustrating the configuration of a part of a semiconductor memory device according to a sixth embodiment.

FIG. 94 is a schematic circuit diagram illustrating the configuration of a part of a semiconductor memory device according to a seventh embodiment.

FIG. 95 is a schematic perspective view illustrating the configuration of a part of the semiconductor memory device according to the seventh embodiment.

FIG. 96 is a schematic XY cross-sectional view illustrating the configuration of a part of a memory layer ML7.

FIG. 97 illustrates a cross section of a structure illustrated in FIG. 96 taken along A-A′ line.

FIG. 98 illustrates a cross section of the structure illustrated in FIG. 96 taken along B-B′ line.

### DETAILED DESCRIPTION

A semiconductor memory device that operates suitably is provided.

In general, according to one embodiment, a semiconductor memory device, comprises: a substrate; a plurality of first semiconductor layers stacked in a first direction intersecting a surface of the substrate; a first via wiring extending in the first direction and electrically connected to the plurality of first semiconductor layers; a plurality of memory units stacked in the first direction and electrically connected to the plurality of first semiconductor layers; a plurality of first gate electrodes stacked in the first direction and facing the plurality of first semiconductor layers; a plurality of first wirings stacked in the first direction, extending in a second direction intersecting the first direction, and electrically connected to the plurality of first gate electrodes; a plurality of second semiconductor layers stacked in the first direction and electrically connected to the plurality of first gate electrodes via the plurality of first wirings; a second via wiring extending in the first direction and electrically connected to the plurality of second semiconductor layers; and a plurality of second gate electrodes stacked in the first direction and facing the plurality of second semiconductor layers. The plurality of second semiconductor layers include a material that is different from any material included in the plurality of first semiconductor layers, or a composition ratio of materials included in the plurality of second semiconductor layers is different from a composition ratio of materials included in the plurality of first semiconductor layers.

Next, a semiconductor memory device according to embodiments will be described in detail with reference to the drawings. Note that the following embodiments are merely examples, and are not illustrated with the intention of limiting the present invention. Additionally, the following drawings are schematic and some components and the like may be omitted for convenience of description. Additionally, the same numerals are assigned to elements that are common to a plurality of embodiments, and a description thereof may not be repeated.

Additionally, in this specification, a “semiconductor memory device” may mean a memory die, or may mean a memory system including a controller die, such as a memory chip, a memory card, and an SSD (Solid State Drive). Further, it may mean a device including a host computer, such as a smart phone, a tablet terminal, and a personal computer.

Additionally, in this specification, when a first component is “electrically connected to” a second component, the first component may be directly connected to the second component, or the first component may be connected to the second component via wiring, a semiconductor member, a transistor, or the like. For example, when three transistors are connected in series, even if a second transistor is in an OFF state, a first transistor is “electrically connected” to a third transistor.

Additionally, in this specification, when the first component is “electrically connected between” the second component and the third component, it may mean that the first component, the second component, and the third component are connected in series, and the second component is electrically connected to the third component via the first component.

Additionally, in this specification, when a circuit or the like “conducts” two wirings, it may mean that, for example, the circuit or the like includes a transistor and the like, the transistor is provided in a current path between the two wirings, and the transistor is in an ON state.

Additionally, in this specification, a direction parallel to an upper surface of a substrate is called an X direction, a direction parallel to the upper surface of the substrate and perpendicular to the X direction is called a Y direction, and a direction perpendicular to the upper surface of the substrate is called a Z direction.

Additionally, in this specification, a direction intersecting a surface of the substrate may be called a stacking direction. Additionally, a direction intersecting the stacking direction and along the surface may be called a first direction, and a direction along this surface and intersecting the first direction may be called a second direction. The stacking direction may or may not coincide with the Z direction. Additionally, the first direction and the second direction may or may not correspond to one of the X direction and the Y direction.

Additionally, in this specification, expressions such as “upward”, “downward”, and the like are used with respect to the substrate. For example, a direction away from the substrate along the above-described Z direction is called an upward direction, and a direction closer to the substrate along the Z direction is called a downward direction. Additionally, it is assumed that a lower surface and a lower end of a certain component mean a surface and an end on the substrate side of this component, and an upper surface and an upper end mean a surface and an end of this component on the opposite side of the substrate. Additionally, a surface intersecting the X direction or the Y direction is called a side surface or the like.

Additionally, in this specification, a “center position” of a certain component may mean, for example, the position of the center of the circumscribed circle of this component, or may mean the center of gravity on an image of this component.

### First Embodiment

### [Circuit Configuration]

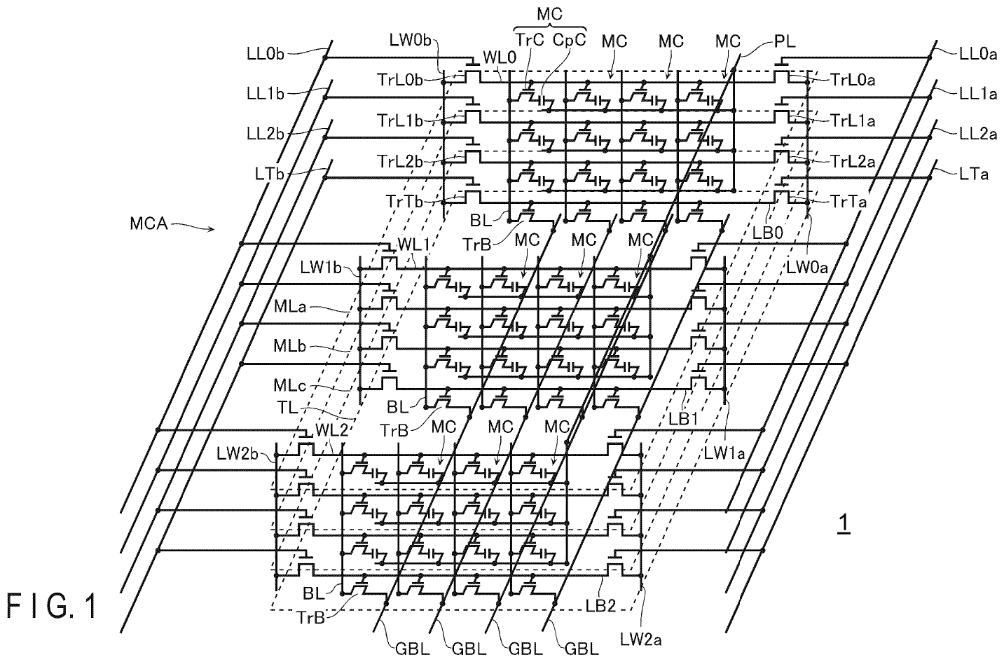

FIG. 1 is a schematic circuit diagram illustrating the configuration of a semiconductor memory device according to a first embodiment. As illustrated in FIG. 1, the semiconductor memory device according to the present embodiment includes a memory cell array MCA. The memory cell array MCA includes: a plurality of memory layers MLa to MLc (hereinafter may be referred to as “memory layers ML”), a transistor layer TL, a plurality of bit lines BL connected to these plurality of memory layers ML and the transistor layer TL, a plurality of global bit lines GBL electrically connected to the plurality of bit lines BL via the transistor layer TL, and a plate line PL connected to the plurality of memory layers ML.

The memory layers ML include a plurality of word lines WL0 to WL2 (hereinafter may be referred to as “word lines WL”), and a plurality of memory cells MC connected to these plurality of word lines WL0 to WL2, respectively. Each of the memory cells MC includes a transistor TrC and a capacitor CpC. One electrode of the transistor TrC is connected to the bit line BL. The other electrode of the transistor TrC is connected to the capacitor CpC. Note that the one electrode and the other electrode of the transistor TrC function as a source electrode or a drain electrode in accordance with the voltage applied to the transistor TrC. A gate electrode of the transistor TrC is connected to one of the word lines WL0 to WL2. One electrode of the capacitor CpC is connected to the other electrode of the transistor TrC. The other electrode of the capacitor CpC is connected to the plate line PL.

Note that each bit line BL is connected to the plurality of memory cells MC corresponding to the plurality of memory layers ML.

Additionally, each of the memory layers ML includes a plurality of transistors TrL0a and TrL0b, TrL1a and TrL1b, or TrL2a and TrL2b (hereinafter collectively referred to as “transistors TrL”) provided corresponding to the plurality of word lines WL0 to WL2. One electrode of each of the transistors TrL is connected to any of the word lines WL0 to WL2. Another electrode of each of the transistors TrL is connected to any of word line selection lines LW0a, LW0b, LW1a, LW1b, LW2a, and LW2b (hereinafter may be referred to as “word line selection lines LW”). Note that the one electrode and the other electrode of each transistor TrL function as a source electrode or a drain electrode according to the voltage applied to the transistor TrL. The gate electrode of each of the transistors TrL is connected to any of layer selection lines LL0a, LL0b, LL1a, LL1b, LL2a, and LL2b (hereinafter may be referred to as “layer selection lines LL”).

Note that the word line selection lines LW are connected to the plurality of transistors TrL corresponding to the plurality of memory layers ML. Additionally, each of the layer selection lines LL0a, LL1a, and LL2a is commonly connected to all the transistors TrL0a, TrL1a, or TrL2a in the corresponding memory layer ML (i.e., MLa, MLb, or MLc). Similarly, each of the layer selection lines LL0b, LL1b, and LL2b is commonly connected to all the transistors TrL0b, TrL1b, or TrL2b in the corresponding memory layer ML.

The transistor layer TL includes a plurality of bit line selection lines LB0 to LB2 (hereinafter may be referred to as “bit line selection lines LB”), and a plurality of transistors TrB connected to the plurality of bit line selection lines LB0 to LB2. One electrode of each transistor TrB is connected to one of global bit lines GBL. The other electrode of the transistor TrB is connected to a bit line BL. Note that the one electrode and the other electrode of each transistor TrB function as a source electrode or a drain electrode according to the voltage applied to the transistor TrB. A gate electrode of the transistor TrB is connected to one of the bit line selection lines LB0 to LB2.

Additionally, the transistor layer TL includes a plurality of transistors TrTa and TrTb (hereinafter may be referred to as “transistors TrT”) provided corresponding to each of the plurality of bit line selection lines LB0 to LB2. One electrode of each transistors TrT is connected to any of the bit line selection lines LB0 to LB2. The other electrode of the transistor TrT is connected to a corresponding word line selection line LW. Note that the one electrode and the other electrode of each transistor TrT function as a source electrode or a drain electrode according to the voltage applied to the transistor TrT. A gate electrode of the transistor TrT is connected to one of wirings LTa and LTb (hereinafter may be referred to as “wiring LT”).

Note that the wiring LTa is commonly connected to all the transistors TrTa. Similarly, the wiring LTb is commonly connected to all the transistors TrTb.

### [Read Operation]

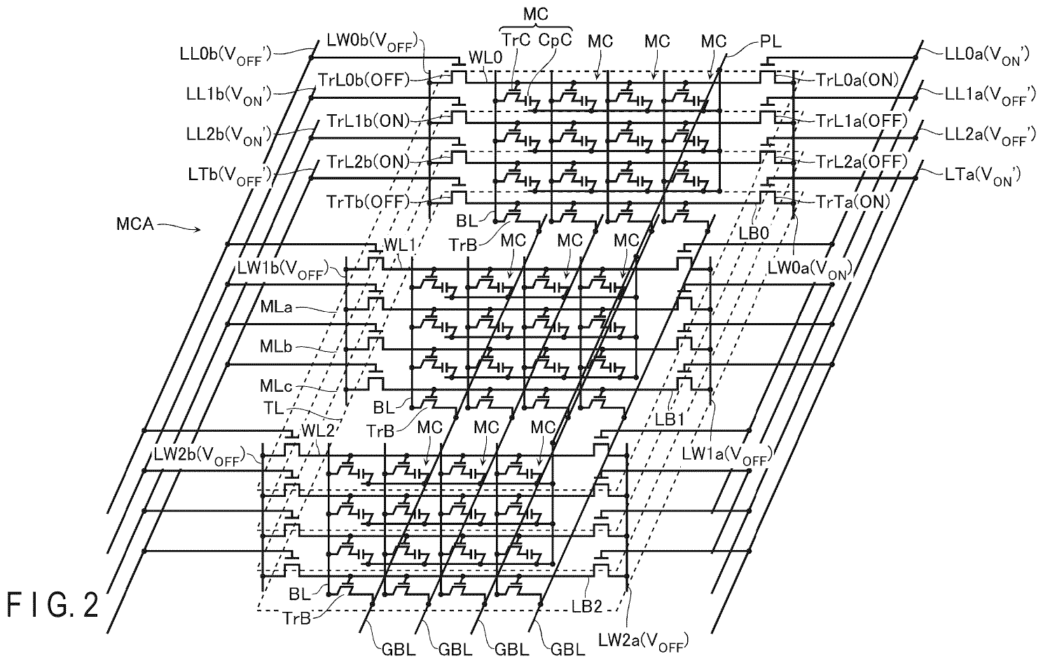

FIG. 2 is a schematic circuit diagram for describing a read operation of the semiconductor memory device according to the first embodiment.

At the time of a read operation, one of the plurality of memory layers MLa to MLc is selected. In the illustrated example, the memory layer MLa is selected. At the time of selection of the memory layers MLa to MLc, for example, among the plurality of layer selection lines LL0a, LL1a, and LL2a, a voltage VON′ is applied to the layer selection line LL0a corresponding to the memory layer MLa, which is the target of the read operation, and a voltage VOFF′ is applied to the other layer selection lines LL1a and LL2a. Additionally, for example, among the plurality of layer selection lines LL0b, LL1b, and LL2b, the voltage VOFF′ is applied to the layer selection line LL0b corresponding to the memory layer MLa, which is the target of the read operation, and the voltage VON′ is applied to the other layer selection lines LL1b and LL2b. Additionally, the voltage VON′ is applied to the wiring LTa, and the voltage VOFF′ is applied to the wiring LTb.

The voltage VON′ has, for example, a magnitude sufficient to turn the transistors TrL and TrT into an ON state. The voltage VOFF′ has, for example, a magnitude that maintains the transistors TrL and TrT in an OFF state. For example, when the transistors TrL and TrT are NMOS transistors, the voltage VON′ is greater than the voltage VOFF′. Additionally, for example, when the transistors TrL and TrT are PMOS transistors, the voltage VON′ is smaller than the voltage VOFF′.

Additionally, at the time of a read operation, one of the plurality of word lines WL0 to WL2 is selected. In the illustrated example, the word line WL0 is selected. At the time of selection of the word lines WL0 to WL2, for example, among the plurality of word line selection lines LW0a LW1a, and LW2a, the voltage VON is applied to the word line selection line LW0a corresponding to the word line WL0, which is the target of the read operation, and the voltage VOFF is applied to the other layer selection lines LW1a and LW2a. Additionally, for example, the voltage VOFF is applied to the plurality of word line selection lines LW0b, LW1b, and LW2b.

The voltage VON has, for example, a magnitude sufficient to turn the transistors TrC and TrB into an ON state. The voltage VOFF has, for example, a magnitude that maintains the transistors TrC and TrB in an OFF state. For example, when the transistors TrC and TrB are NMOS transistors, the voltage VON is greater than the voltage VOFF. Additionally, for example, when the transistors TrC and TrB are PMOS transistors, the voltage VON is smaller than the voltage VOFF.

Here, the voltage VON is applied to the word line WL0 (hereinafter referred to as a “selected word line WL0”) connected to the memory cell MC (hereinafter referred to as a “selected memory cell MC”), which is the target of the read operation, via the transistor TrL0a. Accordingly, the transistors TrC in the selected memory cell MC are turned into the ON state. Additionally, the voltage VON is applied to the transistors TrB connected to the selected memory cell MC via the transistor TrTa. Accordingly, the transistors TrB are turned into the ON state, and the capacitors CpC in the selected memory cell MC conduct to the global bit lines GBL. In connection with this, the voltage of the global bit lines GBL is changed, or a current flows through the global bit lines GBL. By detecting this voltage variation or current, it is possible to read the data stored in the selected memory cell MC.

Additionally, the voltage VOFF is applied to the word lines WL1 and WL2 (hereinafter referred to as “non-selected word lines WL1 and WL2”, or the like) other than the selected word line WL0 corresponding to the memory layer MLa of the selected memory cell MC, via the transistor TrL0a. Accordingly, the transistors TrC in the memory cells MC are maintained in the OFF state. Additionally, the voltage VOFF is applied to the transistors TrB connected to such memory cells MC via the transistors TrTa. Accordingly, the transistors TrB are maintained in the OFF state.

Additionally, the voltage VOFF is applied to the non-selected word lines WL0, WL1, and WL2, corresponding to the memory layers MLb and MLc different from the selected memory cell MC, via the transistors TrL1b and TrL2b. Accordingly, the transistors TrC in the memory cell MC are maintained in the OFF state.

### [Voltage Applied in Read Operation]

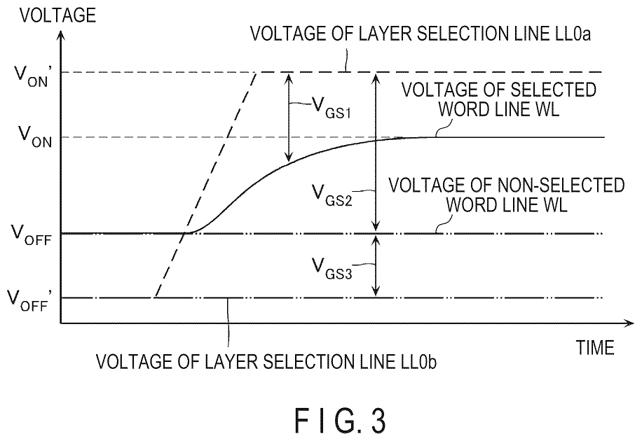

FIG. 3 is a graph illustrating the magnitude relationship of the voltages applied to the word lines WL and the layer selection lines LL in a read operation. The horizontal axis represents the time. The vertical axis represents the magnitude of voltage.

In the read operation, a plurality of transistors TrL (the plurality of transistors TrL0a in the example of FIG. 2) are turned into an ON state in the memory layer ML including the selected memory cell MC. Accordingly, gate-source voltages VGS1 and VGS2 of these transistors TrL are higher than a threshold voltage of the transistors TrL.

Among these transistors TrL, the gate-source voltage VGS1 of the one connected to the selected word line WL is decreased when the voltage of the selected word line WL is increased, and becomes the voltage obtained by subtracting the voltage VON applied to the word line selection line LW from the voltage VON′ applied to the layer selection line LL.

Among these transistors TrL, the gate-source voltage VGS2 of the one connected to the non-selected word line WL is the voltage obtained by subtracting the voltage VOFF applied to the word line selection line LW from the voltage VON′ applied to the layer selection line LL.

Additionally, in the read operation, in the memory layer ML including the selected memory cell MC, a plurality of transistors TrL (a plurality of transistors TrL0b in the example of FIG. 2) are maintained in an OFF state. Accordingly, the gate-source voltage VGS3 of these transistors TrL is lower than the threshold voltage of the transistors TrL.

Among these transistors TrL, the gate-source voltage VGS3 of the one connected to the non-selected word line WL is the voltage obtained by subtracting the voltage VOFF applied to the word line selection line LW from the voltage VOFF′ applied to the layer selection line LL. FIG. 3 illustrates an example in which the gate-source voltage VGS3 is a negative magnitude.

### [Threshold Voltage of Transistor TrL]

In a read operation, in order to apply the voltage VON to the selected word line WL at high speed, it is desirable to maintain the gate-source voltage VGS1 of the transistors TrL corresponding to the selected memory cell MC at a state sufficiently higher than the threshold voltage of the transistors TrL, and increase the current flowing through the transistors TrL. For this purpose, it is conceivable to set the voltage VON′ to a large value.

However, when the voltage VON is set to a large value, the gate-source voltage VGS2 of a part of the transistors TrL becomes high, and it becomes necessary to configure the transistors TrL to be able to withstand a higher voltage. For that purpose, it is conceivable to thicken a gate insulating film of the transistors TrL. However, when the gate insulating film of the transistors TrL is thickened, the length of the entire memory layer ML in the Z direction is increased, which hinders high integration of a semiconductor memory device.

Therefore, in the present embodiment, the threshold voltage of the transistors TrL is set to a lower value (for example, a value lower than a threshold voltage of the transistors TrC). According to such a configuration, it is possible to apply the voltage VON to the selected word line WL at high speed, without setting the voltage VON′ to a large value, and without hindering high integration of a semiconductor memory device.

Note that it is conceivable to set a lower value not only to the threshold voltage of the transistors TrL, but also to the threshold voltage of the transistors TrC. However, when the threshold voltage of the transistors TrC is low, a leakage current occurs in the transistors TrC, and there is a possibility that retention of data becomes difficult. Therefore, it is desirable that the threshold voltage of the transistors TrC is not set to a lower value.

### [Structure]

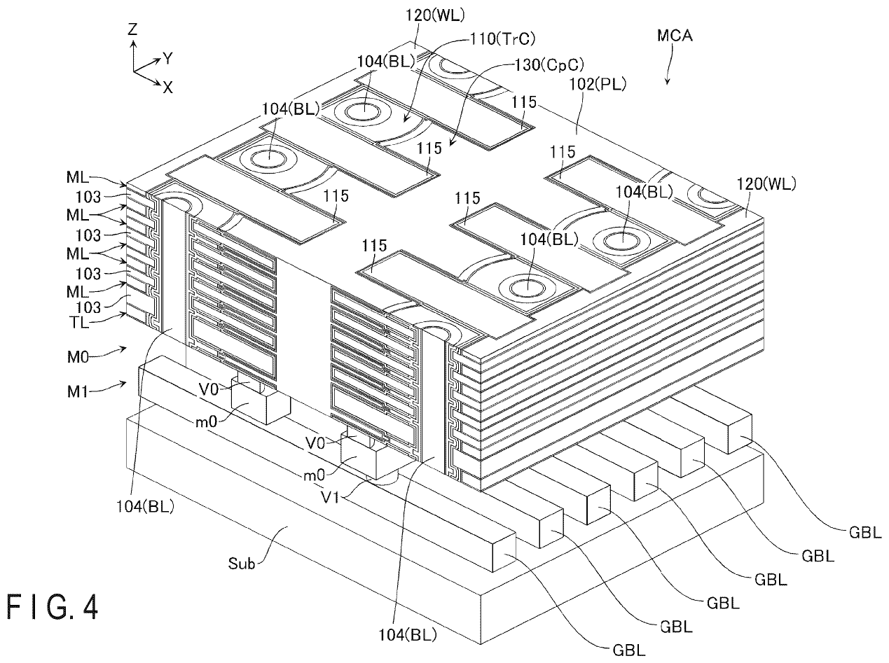

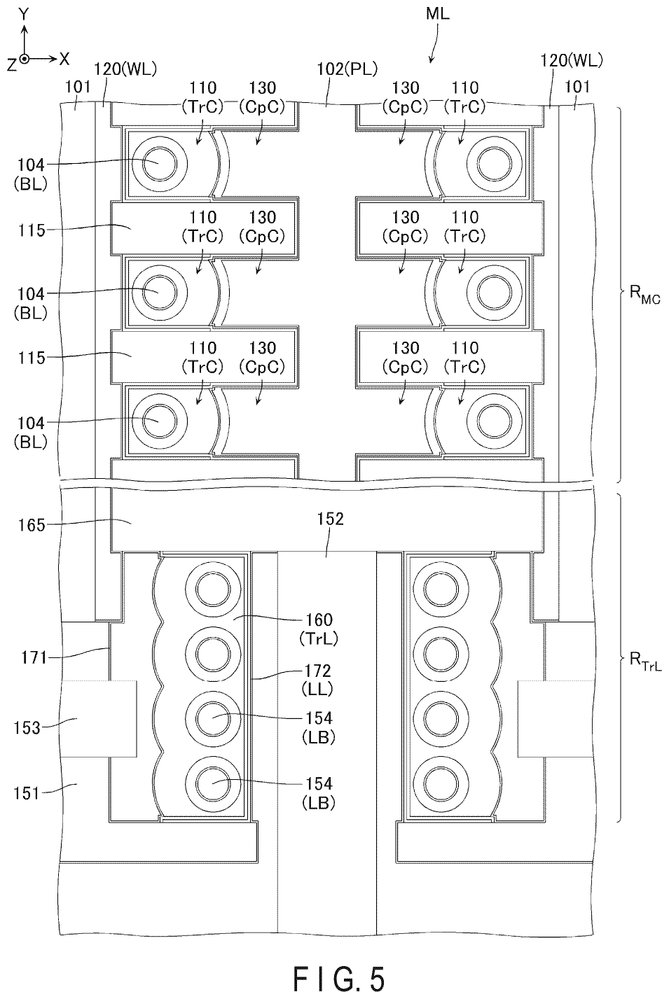

FIG. 4 is a schematic perspective view illustrating the configuration of a part of the semiconductor memory device according to the present embodiment. FIG. 4 illustrates a part of a semiconductor substrate Sub, and a memory cell array MCA provided above the semiconductor substrate Sub.

The semiconductor substrate Sub is, for example, a semiconductor substrate made from silicon (Si) or the like containing a P-type impurity such as boron (B). An insulating layer and an electrode layer, which are not illustrated, are provided on an upper surface of the semiconductor substrate Sub. The upper surface of the semiconductor substrate Sub, and the insulating layer and the electrode layer, which are not illustrated, constitute a control circuit for controlling the semiconductor memory device according to the first embodiment. For example, a sense amplifier circuit is provided in an area directly under the memory cell array MCA. The sense amplifier circuit is electrically connected to the bit line BL via the global bit line GBL. The sense amplifier circuit can read data stored in the selected memory cell MC by detecting the voltage variation or current in the bit line BL in a read operation.

The memory cell array MCA includes a plurality of memory layers ML stacked in the Z direction, a transistor layer TL provided between the memory layers ML and the semiconductor substrate Sub, a wiring layer M0 provided between the transistor layer TL and the semiconductor substrate Sub, and a wiring layer M1 provided between the wiring layer M0 and the semiconductor substrate Sub. Additionally, an insulating layer 103 made from silicon oxide (SiO₂) or the like is provided between the plurality of memory layers ML, and between the lowermost memory layer ML and the transistor layer TL.

FIG. 5 is a schematic XY cross-sectional view illustrating the configuration of a part of the memory layer ML. As illustrated in FIG. 5, the memory layer ML includes a memory cell area RMC and a transistor area RTrL. Although illustration is omitted, the transistor area RTrL is provided on both sides of the memory cell area RMC in the Y direction.

### [Structure of Memory Cell Area RMC]

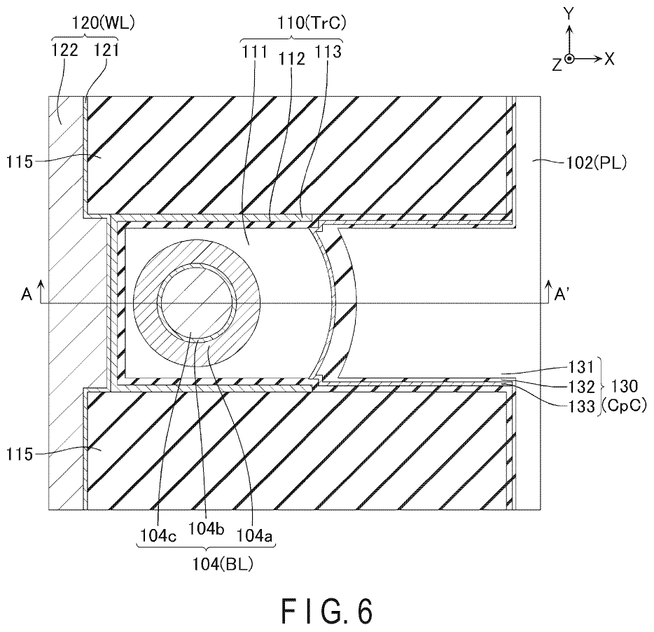

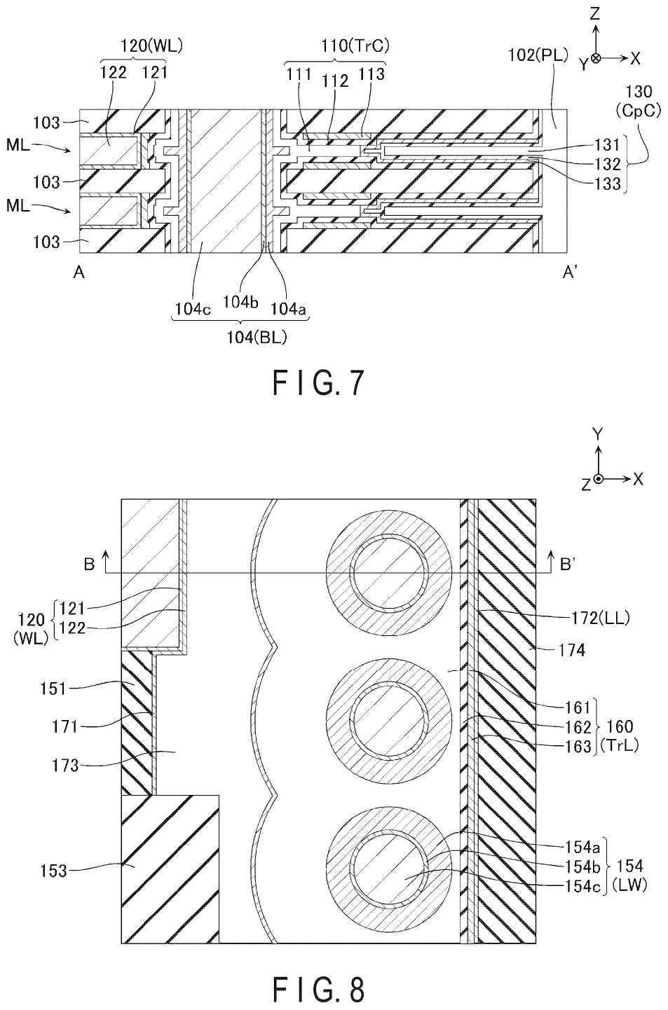

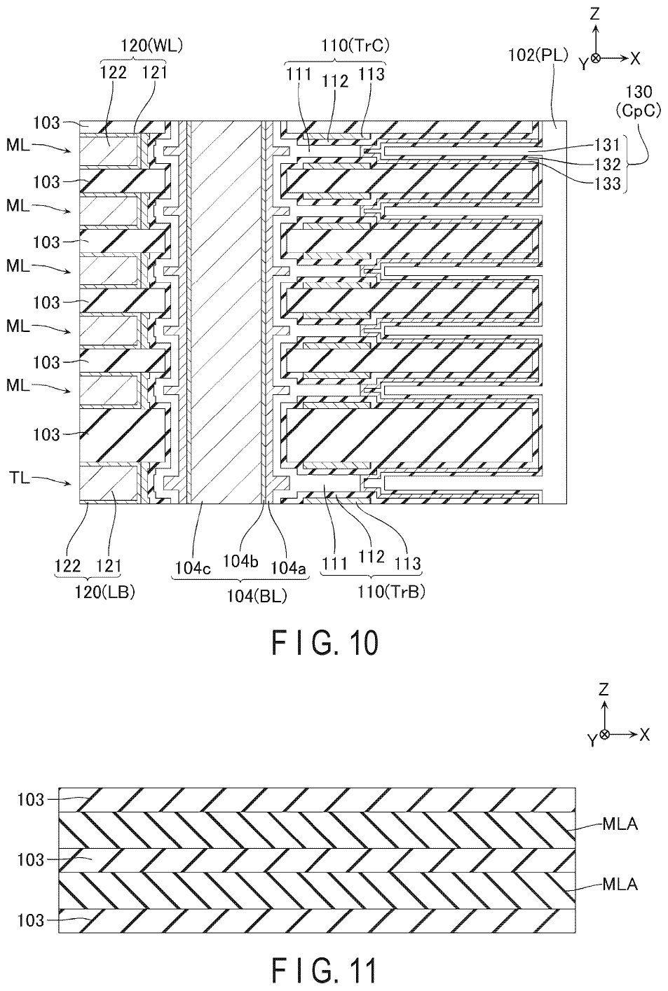

Next, the structure of the memory cell area RMC will be described with reference to FIG. 6, FIG. 7, and FIG. 10, in addition to FIG. 4 and FIG. 5. FIG. 6 is a schematic XY cross-sectional view illustrating the configuration of a part of the memory layer ML, and illustrates a part of FIG. 5 in an enlarged manner. FIG. 7 illustrates a cross section of the structure illustrated in FIG. 6 taken along A-A′ line. FIG. 10 is a schematic cross-sectional view illustrating the configuration of the semiconductor memory device according to the present embodiment.

As illustrated in FIG. 5, the memory cell area RMC includes a plurality of insulating layers 101 arranged in the X direction, and a conductive layer 102 provided between two insulating layers 101 that are adjacent to each other in the X direction. The insulating layers 101 and the conductive layer 102 extend in the Y direction and the Z direction, and divide the plurality of memory layers ML in the X direction (see FIG. 4).

The insulating layer 101 includes, for example, silicon oxide (SiO₂) or the like.

The conductive layer 102 can include, for example, a layered structure of titanium nitride (TiN) and tungsten (W), or the like. Additionally, the conductive layer 102 may contain, for example, a conductive oxide. Note that, instead of the conductive oxide, the conductive layer 102 may contain ruthenium (Ru), iridium (Ir), or other metals. Additionally, the conductive layer 102 may contain only the conductive oxide, or may contain only ruthenium (Ru), iridium (Ir), or other metals. The conductive layer 102 functions as, for example, the plate line PL (see FIG. 1).

In the specification, it is assumed that “the conductive oxide” includes, for example, indium tin oxide (ITO), indium zinc oxide (IZO), ruthenium oxide (RuO2), iridium oxide (IrO2), or other oxygen-containing conductive material.

A plurality of via wirings 104 are provided in an area between the insulating layer 101 and the conductive layer 102. The plurality of via wirings 104 are arranged in the Y direction, and extend in the Z direction through the plurality of memory layers ML as illustrated in, for example, FIG. 4.

As illustrated in FIG. 7, the via wiring 104 includes a conductive oxide film 104a including a conductive oxide, a barrier conductive film 104b made from titanium nitride (TiN) or the like, and a conductive member 104c made from tungsten (W) or the like. Note that, instead of the conductive oxide film 104a, the via wiring 104 may contain ruthenium (Ru), iridium (Ir), or other metals. Additionally, the via wiring 104 may contain only the conductive oxide, or may contain only ruthenium (Ru), iridium (Ir), or other metals.

The conductive member 104c has a substantially columnar shape extending in the Z direction. The barrier conductive film 104b has a substantially cylindrical shape extending in the Z direction along the outer peripheral surface of the conductive member 104c. The conductive oxide film 104a has a substantially cylindrical shape extending in the Z direction along the outer peripheral surface of the barrier conductive film 104b.

The via wiring 104 functions as, for example, the bit line BL (see FIG. 1). As illustrated in, for example, FIG. 1, the plurality of bit lines BL are provided corresponding to the plurality of transistors TrC included in the memory layer ML.

The memory layer ML includes a plurality of transistor structures 110 provided corresponding to the plurality of via wirings 104, a conductive layer 120 provided on the opposite side of the conductive layer 102 with respect to the plurality of transistor structures 110, and a plurality of capacitor structures 130 provided between the plurality of transistor structures 110 and the conductive layer 102.

As illustrated in, for example, FIG. 6, the transistor structure 110 includes: a semiconductor layer 111 connected to the outer peripheral surface of the via wiring 104 and extending in the X direction; an insulating layer 112 provided to an upper surface, a lower surface, both side surfaces in the Y direction, and a side surface on the conductive layer 120 side in the X direction of the semiconductor layer 111; and a conductive layer 113 provided to an upper surface, a lower surface, both side surfaces in the Y direction, and a side surface on the conductive layer 120 side in the X direction of the insulating layer 112.

In an XY cross-section as exemplified in FIG. 6, a side surface of the semiconductor layer 111 on the conductive layer 102 side in the X direction may be formed along a circle centered on the center position of the via wiring 104. Additionally, the side surfaces of the semiconductor layer 111, the insulating layer 112, and the conductive layer 113 on the other side (i.e., the conductive layer 120 side) in the X direction may be formed in a straight line along a side surface of the conductive layer 120. Additionally, both side surfaces of the semiconductor layer 111, the insulating layer 112, and the conductive layer 113 in the Y direction may be formed in a straight line along side surfaces of the insulating layers 115.

The semiconductor layer 111 functions as, for example, a channel area of the transistor TrC (see FIG. 1). The semiconductor layer 111 may be, for example, a semiconductor containing at least one element of gallium (Ga) and aluminum (Al), indium (In), zinc (Zn), and oxygen (O), or may be other oxide semiconductor. A plurality of semiconductor layers 111 arranged in the Z direction are commonly connected to the via wiring 104 extending in the Z direction.

The insulating layer 112 functions as, for example, a gate insulating film of the transistor TrC (see FIG. 1). The insulating layer 112 includes, for example, silicon oxide (SiO₂) or the like.

The conductive layer 113 functions as, for example, a gate electrode of the transistor TrC (see FIG. 1). The conductive layer 113 contains, for example, a conductive oxide such as titanium nitride (TiN) and indium tin oxide (ITO). A plurality of conductive layers 113 arranged in the Y direction are commonly connected to the conductive layer 120 extending in the Y direction (see FIG. 5). The conductive layer 113 faces the upper surface, the lower surface, both side surfaces in the Y direction, and the side surface on the conductive layer 120 side in the X direction of the semiconductor layer 111 via the insulating layer 112.

The insulating layer 115 made from silicon oxide (SiO₂) or the like is provided between two semiconductor layers 111 that are adjacent to each other in the Y direction. The insulating layer 115 extends in the Z direction through the plurality of memory layers ML.

The conductive layer 120 functions as, for example, the word line WL (see FIG. 1). The conductive layer 120 extends in the Y direction, and is connected to the plurality of conductive layers 113 arranged in the Y direction. The conductive layer 120 includes, for example, a barrier conductive film 121 made from titanium nitride (TiN) or the like, and a conductive film 122 made from tungsten (W) or the like.

As illustrated in, for example, FIG. 6 and FIG. 7, the capacitor structure 130 includes: a conductive layer 131; an insulating layer 132 provided to an upper surface, a lower surface, both side surfaces in the Y direction, and a side surface on the transistor structure 110 side in the X direction of the conductive layer 131; and a conductive layer 133 provided to an upper surface, a lower surface, both side surfaces in the Y direction, and a side surface on the transistor structure 110 side in the X direction of the insulating layer 132.

The conductive layer 131 functions as one electrode of the capacitor CpC (see FIG. 1). The conductive layer 131 can include, for example, a layered structure of titanium nitride (TiN) and tungsten (W), or the like. Additionally, the conductive layer 131 may contain, for example, a conductive oxide. Note that, instead of the conductive oxide, the conductive layer 131 may contain ruthenium (Ru), iridium (Ir), or other metals. Additionally, the conductive layer 131 may contain only the conductive oxide, or may contain only ruthenium (Ru), iridium (Ir), or other metals. The conductive layer 131 is continuous with the conductive layer 102.

The insulating layer 132 functions as an insulating layer of the capacitor CpC (see FIG. 1). The insulating layer 132 may be, for example, zirconia (ZrO2), alumina (Al₂O₃), or other insulating metal oxides. Additionally, the insulating layer 132 may be, for example, a stacked film of a plurality of insulating metal oxides (for example, a stacked film of zirconia and alumina).

The conductive layer 133 functions as, for example, the other electrode of the capacitor CpC (see FIG. 1). The conductive layer 133 contains, for example, a conductive oxide such as indium tin oxide (ITO). The conductive layer 133 is insulated from the conductive layer 131 via the insulating layer 132. The conductive layer 133 is connected to a side surface of the semiconductor layer 111 in the X direction.

The transistor layer TL is configured similarly to the memory layer ML. However, in an example of FIG. 10, the length of the transistor layer TL in the Z direction is larger than the length of the memory layer ML in the Z direction. Additionally, the length of the insulating layer 103 in the Z direction provided between the transistor layer TL and the memory layer ML adjacent to the transistor layer TL is larger than the lengths of the other insulating layers 103 in the Z direction. The semiconductor layer 111, the insulating layer 112, and the conductive layer 113 in the transistor layer TL function as a channel area, a gate insulating film, and a gate electrode of the transistor TrB, respectively. Additionally, the conductive layer 120 in the transistor layer TL functions as the bit line selection line LB. Additionally, the conductive layer 133 in the transistor layer TL functions as a source electrode or a drain electrode of the transistor TrB.

The lengths of the insulating layer 112 and the conductive layer 113 in the transistor layer TL in the Z direction are similar to the lengths of the insulating layer 112 and the conductive layer 113 in the memory layer ML in the Z direction. On the other hand, the length of the semiconductor layer 111 in the transistor layer TL in the Z direction is larger than the length of the semiconductor layer 111 in the memory layer ML in the Z direction. According to such a configuration, it is possible to suppress deterioration of electron mobility in the semiconductor layer 111 in the transistor layer TL, and increase the current in the ON state of the transistor TrB to apply voltage to the bit line BL and the global bit line GBL at high speed. Additionally, such a configuration can be realized without hindering high integration of the memory cell array MCA in the Z direction, since it is not necessary to increase the length of the memory layer ML in the Z direction.

As illustrated in FIG. 4, the wiring layer M1 includes the plurality of global bit lines GBL arranged in the Y direction and extending in the X direction. The wiring layer M0 is provided corresponding to a plurality of conductive layers 133, and includes a plurality of wirings m0 arranged in the Y direction.

The wiring m0 is connected to the conductive layer 133 in the transistor layer TL via the via a contact electrode V0 extending in the Z direction. The via contact electrode V0 is provided at a position that overlaps with the conductive layer 133 and wiring m0 when viewed from the Z direction, and includes an upper end connected to the conductive layer 133 and a lower end connected to the wiring m0.

Additionally, the wiring m0 is electrically connected to the global bit line GBL via a via contact electrode V1 extending in the Z direction. The via contact electrode V1 is provided at a position that overlaps with the global bit line GBL and the wiring m0 when viewed from the Z direction, and includes a lower end connected to the global bit line GBL and an upper end connected to the wiring m0.

### [Structure of Transistor Area RTrL]

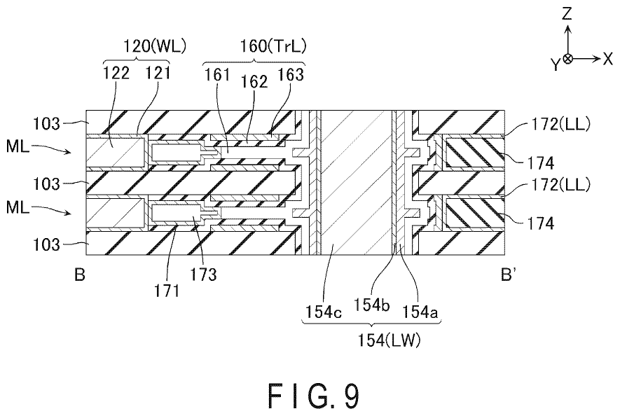

Next, the structure of the transistor area RTrL will be described with reference to FIG. 8 and FIG. 9, in addition to FIG. 4 and FIG. 5. FIG. 8 is a schematic XY cross-sectional view illustrating the configuration of a part of the memory layer ML, and illustrates a part of FIG. 5 in an enlarged manner. FIG. 9 illustrates a cross section of the structure illustrated in FIG. 8 taken along B-B′ line.

As illustrated in FIG. 5, the transistor area RTrL includes a plurality of insulating layers 151 arranged in the X direction corresponding to the plurality of insulating layers 101, and an insulating layer 152 provided between two insulating layers 151 that are adjacent to each other in the X direction. The insulating layer 151 includes a portion extending in the Y direction and the Z direction, and a portion extending in the X direction and the Z direction. The insulating layer 152 extends in the Y direction and the Z direction. The portion of the insulating layer 151 extending in the Y direction and the Z direction, and the insulating layer 152 divide the plurality of memory layers ML in the X direction. The portion of the insulating layer 151 extending in the X direction and the Z direction divides the plurality of memory layers ML in the Y direction. The insulating layer 151 and the insulating layer 152 include, for example, silicon oxide (SiO₂) or the like.

Additionally, an insulating layer 165 extending in the X direction in the range between two conductive layers 120 that are adjacent to each other in the X direction is provided between the memory cell area RMC and the transistor area RTrL. The insulating layer 165 extends in the X direction and the Z direction, and divides the plurality of memory layers ML in the Y direction. The insulating layer 165 includes, for example, silicon oxide (SiO₂) or the like.

Additionally, the insulating layer 151 is divided in the Y direction via an insulating layer 153. The insulating layer 153 extends in the Z direction through the plurality of memory layers ML. The insulating layer 153 includes, for example, silicon oxide (SiO₂) or the like.

A plurality of via wirings 154 are provided in an area between the insulating layer 151 and the insulating layer 152. The plurality of via wirings 154 are arranged in the Y direction, and extend in the Z direction through the plurality of memory layers ML as illustrated in, for example, FIG. 9.

As illustrated in FIG. 9, the via wiring 154 includes a conductive oxide film 154a including a conductive oxide, a barrier conductive film 154b made from titanium nitride (TiN) or the like, and a conductive member 154c made from tungsten (W) or the like. Note that, instead of the conductive oxide film 154a, the via wiring 154 may contain ruthenium (Ru), iridium (Ir), or other metals. Additionally, the via wiring 154 may contain only the conductive oxide, or may contain only ruthenium (Ru), iridium (Ir), or other metals.

The conductive member 154c has a substantially columnar shape extending in the Z direction. The barrier conductive film 154b has a substantially cylindrical shape extending in the Z direction along the outer peripheral surface of the conductive member 154c. The conductive oxide film 154a has a substantially cylindrical shape extending in the Z direction along the outer peripheral surface of the barrier conductive film 154b.

The plurality of via wirings 154 arranged in the Y direction function as, for example, one word line selection line LW (see FIG. 1). As illustrated in, for example, FIG. 1, the plurality of word line selection lines LW are provided corresponding to the plurality of word lines WL included in the memory layer ML.

The memory layer ML includes a plurality of transistor structures 160 provided corresponding to the plurality of conductive layers 120, a wiring 171 provided between the transistor structures 160 and the insulating layer 151, and a wiring 172 provided between the transistor structures 160 and the insulating layer 152.

As illustrated in, for example, FIG. 8, the transistor structure 160 includes: a semiconductor layer 161 connected to the outer peripheral surfaces of the plurality of via wirings 154, and extending in the Y direction along the outer peripheral surfaces of these plurality of via wirings 154; an insulating layer 162 provided to an upper surface, a lower surface, both side surfaces in the Y direction, and a side surface on the insulating layer 152 side in the X direction of the semiconductor layer 161; and a conductive layer 163 provided to an upper surface, a lower surface, both side surfaces in the Y direction, and a side surface on the insulating layer 152 side in the X direction of the insulating layer 162.

In an XY cross-section as exemplified in FIG. 8, the side surface of the semiconductor layer 161 on the insulating layer 151 side in the X direction may be formed along a plurality of circles that are centered on the plurality of center positions of the plurality of via wirings 154 and that overlap with each other. Additionally, the side surfaces of the semiconductor layer 161, the insulating layer 162, and the conductive layer 163 on the other side (i.e., the insulating layer 152 side) in the X direction may be formed in a straight line along the side surface of the wiring 172. Additionally, both side surfaces of the semiconductor layer 161, the insulating layer 162, and the conductive layer 163 in the Y direction may be formed in a straight line along the insulating layer 165 and the portion of the insulating layer 151 extending in the X direction and the Z direction, which have been described with reference to FIG. 5.

The semiconductor layer 161 functions as, for example, a channel area of the transistor TrL (see FIG. 1). The semiconductor layer 161 may be, for example, a semiconductor containing at least one element of gallium (Ga) and aluminum (Al), indium (In), zinc (Zn), and oxygen (O), or may be other oxide semiconductor. A plurality of semiconductor layers 161 arranged in the Z direction are commonly connected to the via wiring 154 extending in the Z direction.

Here, the concentration of indium in the semiconductor layer 161 is higher than the concentration of indium in the semiconductor layer 111. Additionally, the concentration of gallium in the semiconductor layer 161 is equal to or less than the concentration of gallium in the semiconductor layer 111. Accordingly, the threshold voltage of the transistor TrL (see FIG. 1) becomes lower than the threshold voltage of the transistor TrC.

The insulating layer 162 functions as, for example, a gate insulating film of the transistor TrL (see FIG. 1). The insulating layer 162 includes, for example, silicon oxide (SiO₂) or the like.

The conductive layer 163 functions as, for example, a gate electrode of the transistor TrL (see FIG. 1). The conductive layer 163 contains, for example, a conductive oxide such as titanium nitride (TiN) and indium tin oxide (ITO). The side surface of the conductive layer 163 on the insulating layer 152 side in the X direction is connected to the wiring 172. The conductive layer 163 faces the upper surface, the lower surface, both side surfaces in the Y direction, and the side surface on the insulating layer 152 side in the X direction of the semiconductor layer 161 via the insulating layer 162.

The wiring 171 is connected to the conductive layer 120 and the semiconductor layer 161, and has a function of connecting the word line WL (see FIG. 1) to the drain electrode of the transistor TrL. The wiring 171 contains, for example, a conductive oxide. Note that, instead of the conductive oxide, the wiring 171 may contain ruthenium (Ru), iridium (Ir), or other metals. Additionally, the wiring 171 may contain only the conductive oxide, or may contain only ruthenium (Ru), iridium (Ir), or other metals.

The wiring 171 includes, for example, a portion formed on a lower surface of the insulating layer 103 via a part of the insulating layer 162, a portion formed on an upper surface of the insulating layer 103 via a part of the insulating layer 162, a portion formed on a side surface of the conductive layer 120 in the X direction, and a portion formed on a side surface of the semiconductor layer 161 in the X direction. Additionally, a semiconductor layer 173 made from silicon (Si) or the like may be provided in an area surrounded by the wiring 171.

As illustrated in FIG. 5, the wiring 172 includes a portion extending in the Y direction and a portion extending in the X direction. The portion of the wiring 172 extending in the Y direction is connected to the conductive layer 163. The wiring 172 functions as the layer selection line LL (see FIG. 1). The wiring 172 contains, for example, a conductive oxide. Note that, instead of the conductive oxide, the wiring 172 may contain ruthenium (Ru), iridium (Ir), or other metals. Additionally, the wiring 172 may contain only the conductive oxide, or may contain only ruthenium (Ru), iridium (Ir), or other metals.

The wiring 172 includes, for example, a portion formed on the lower surface of the insulating layer 103, a portion formed on the upper surface of the insulating layer 103, and a portion formed on the side surface of the conductive layer 163 in the X direction. Additionally, an insulating layer 174 made from silicon oxide (SiO2) or the like may be provided in an area surrounded by the wiring 172.

The transistor layer TL is formed similarly to the memory layer ML. However, the semiconductor layer 161, the insulating layer 162, and the conductive layer 163 in the transistor layer TL function as the channel area, the gate insulating film, and the gate electrode of the transistor TrT, respectively. Additionally, the wiring 171 in the transistor layer TL functions as the bit line selection line LB. Additionally, the wiring 172 in the transistor layer TL functions as the wiring LT.

### [Manufacturing Method]

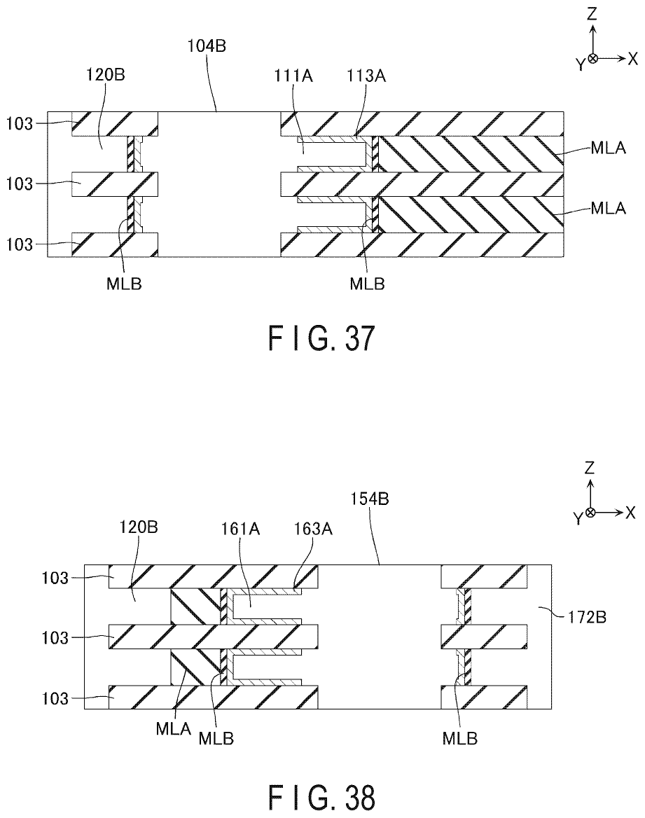

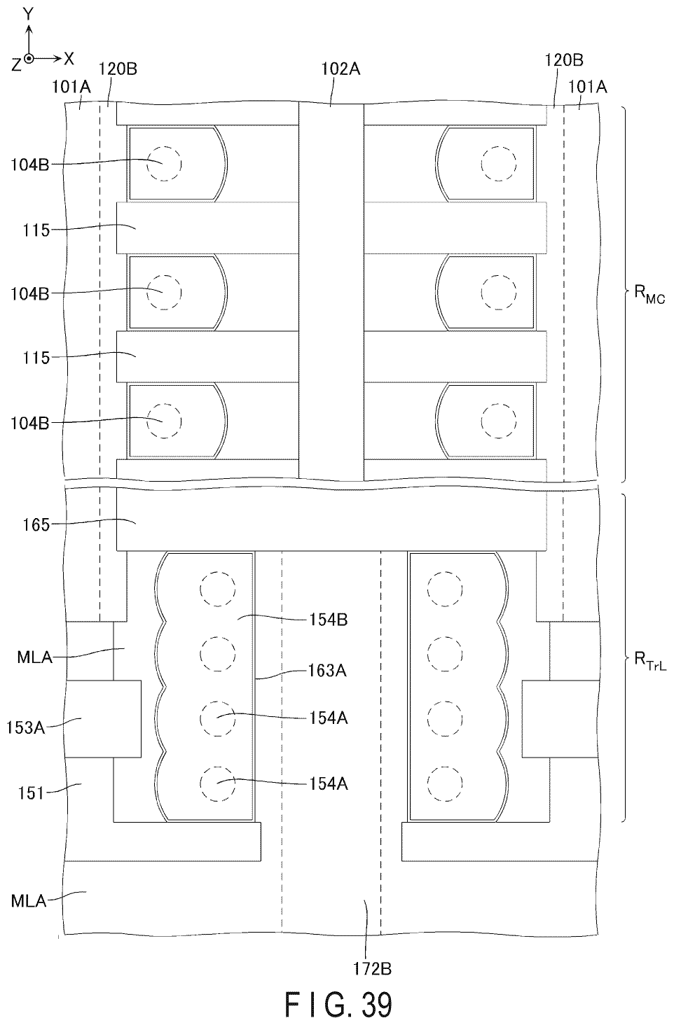

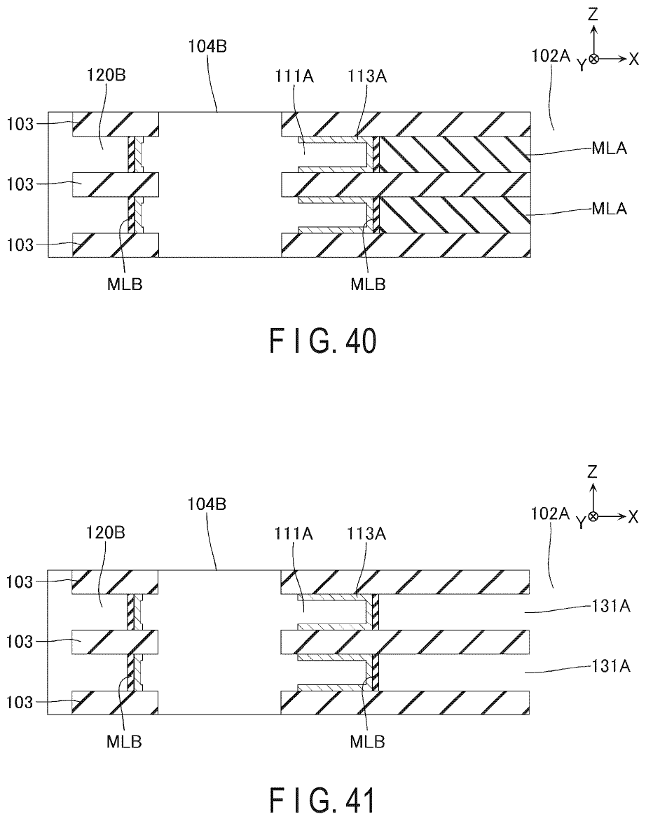

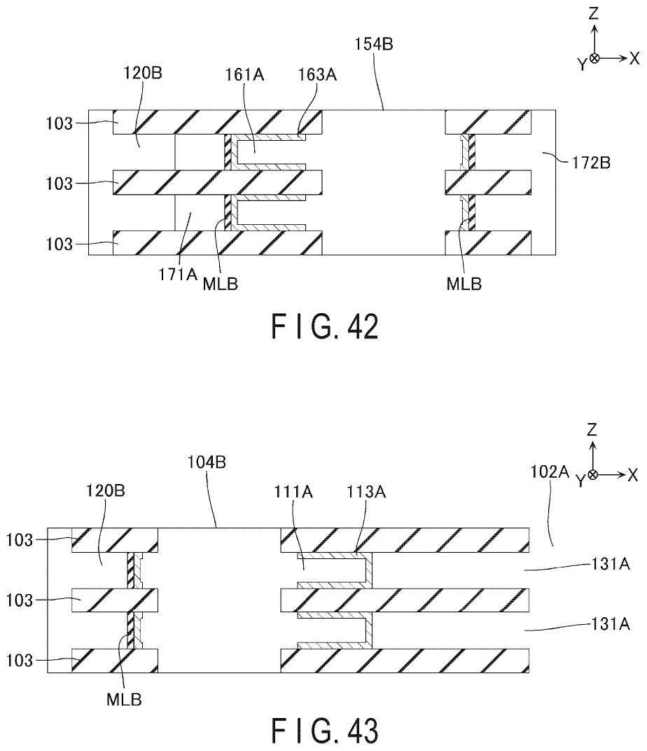

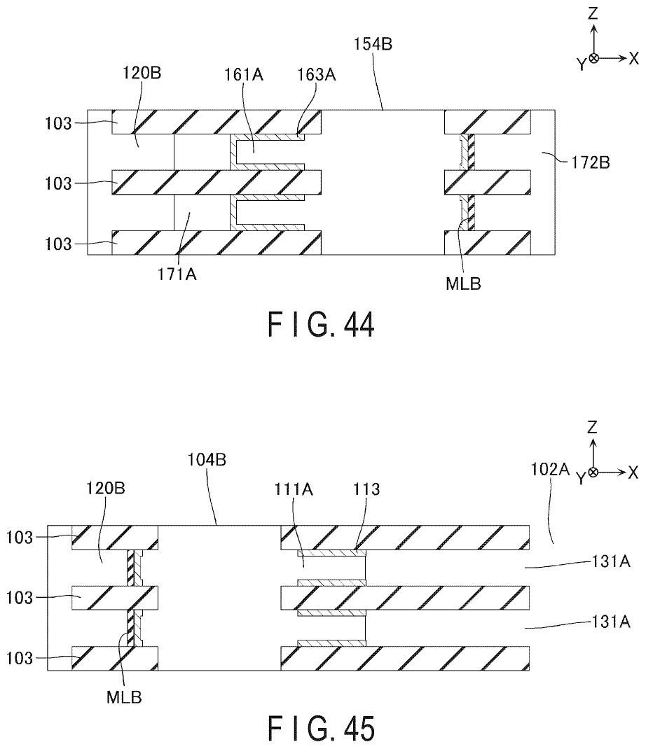

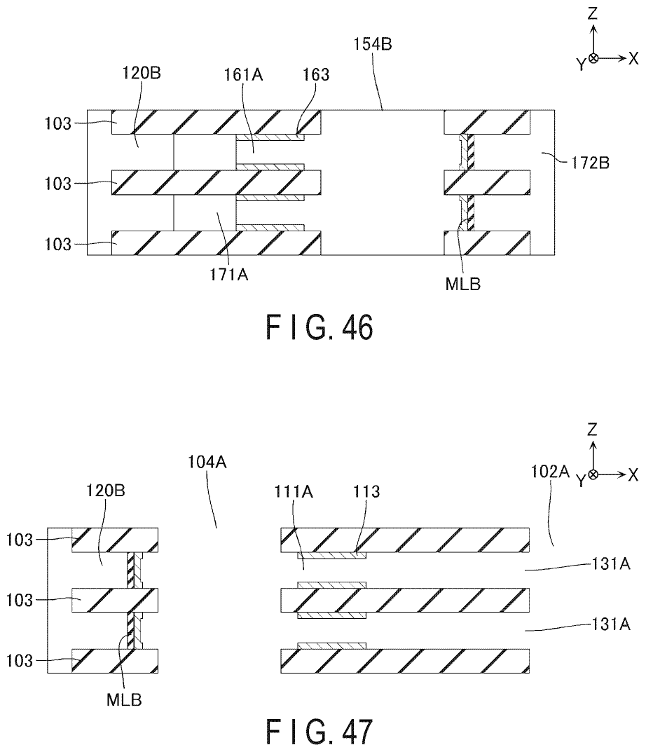

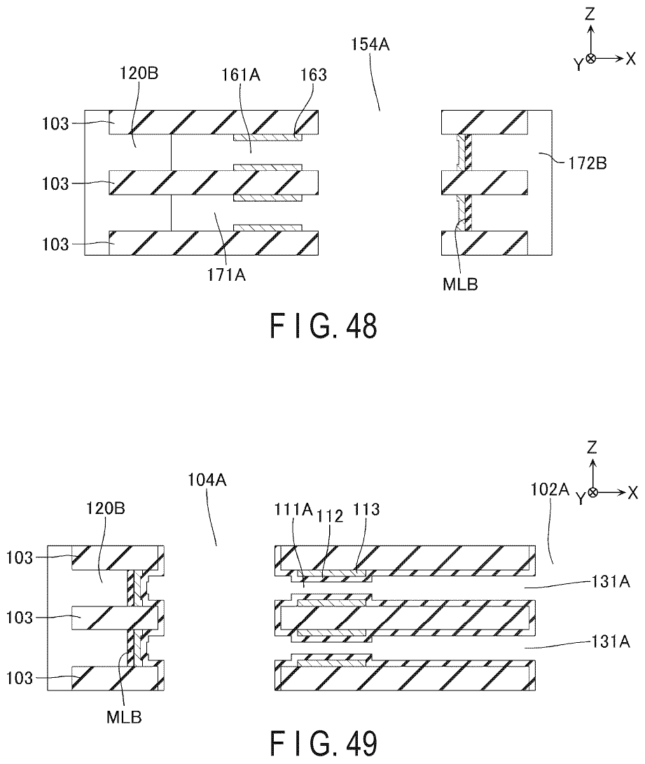

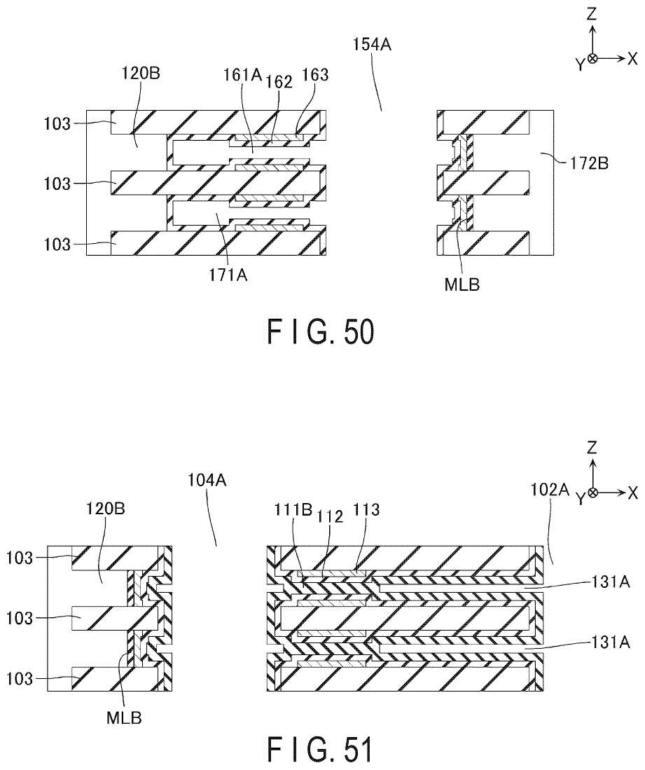

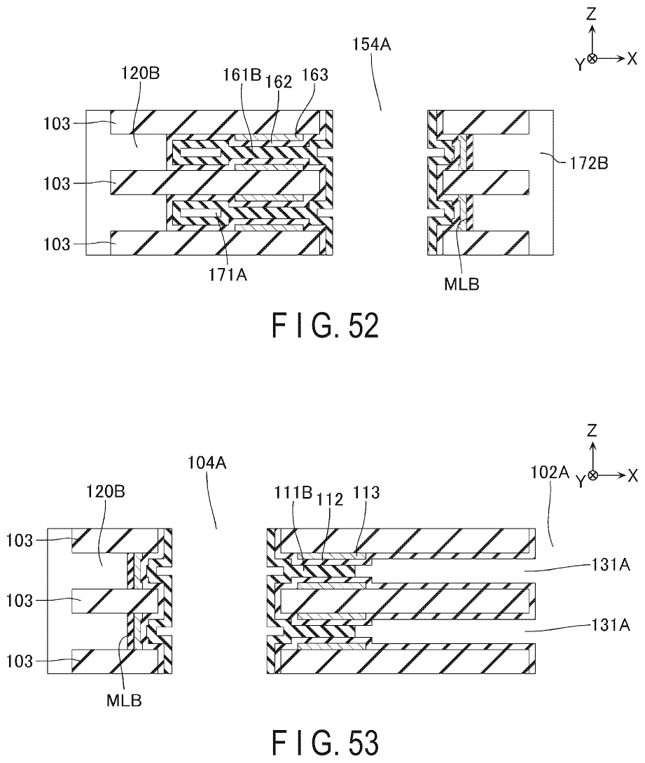

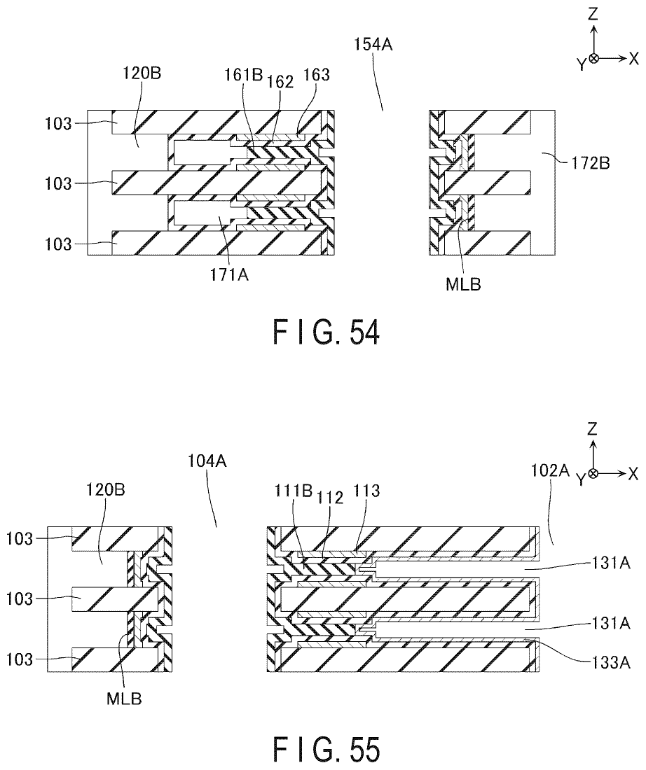

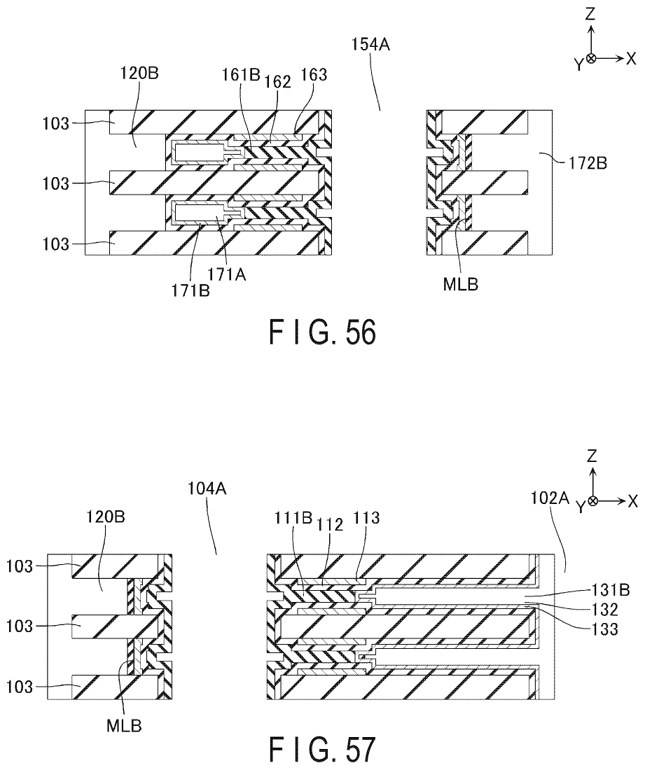

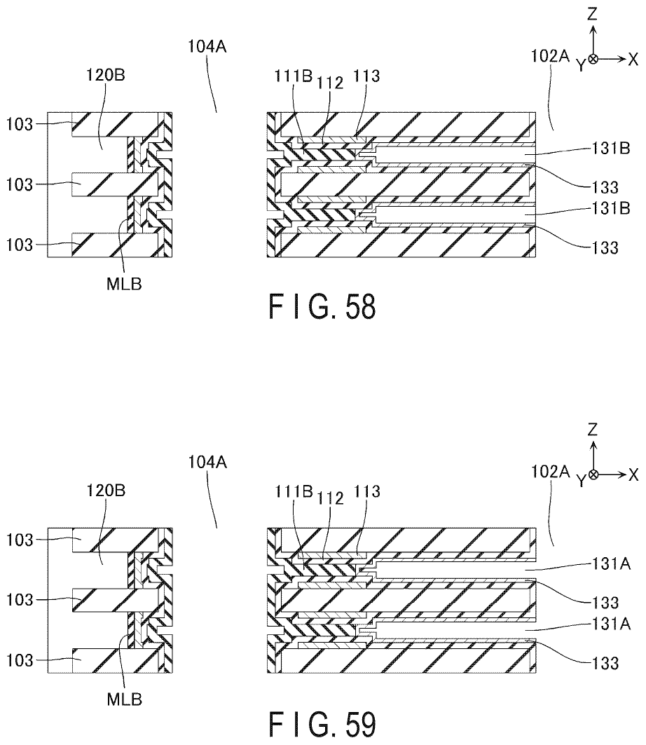

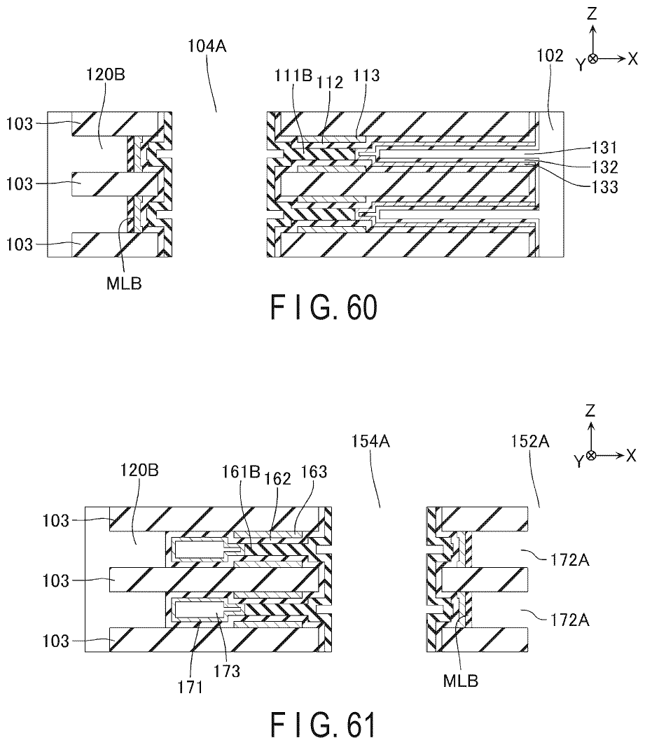

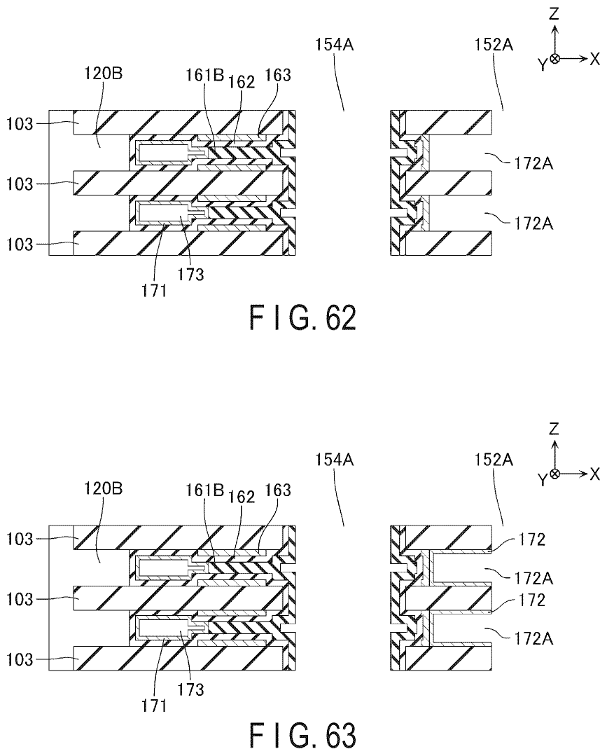

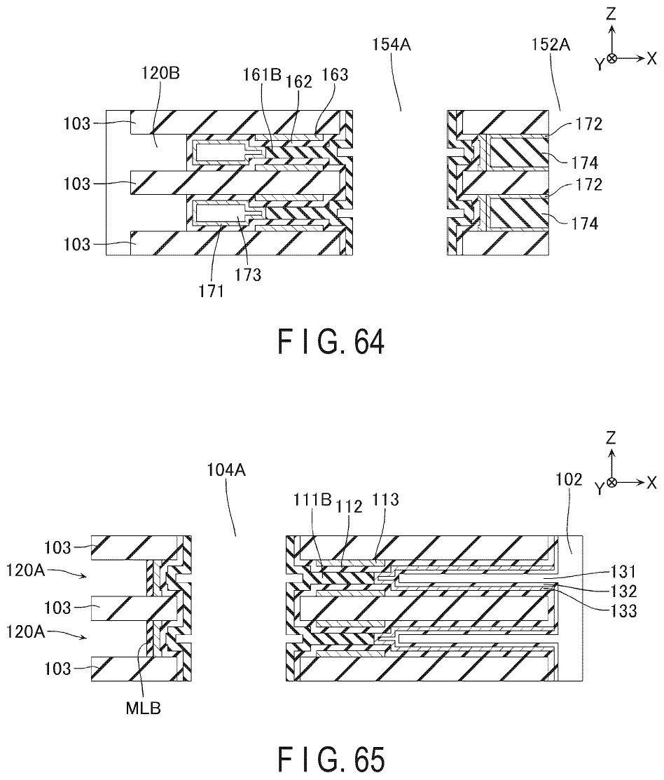

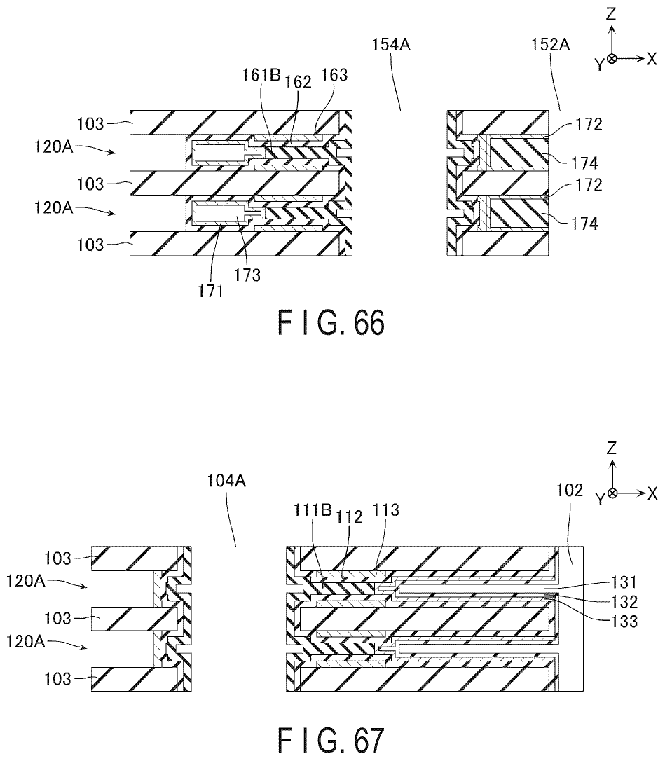

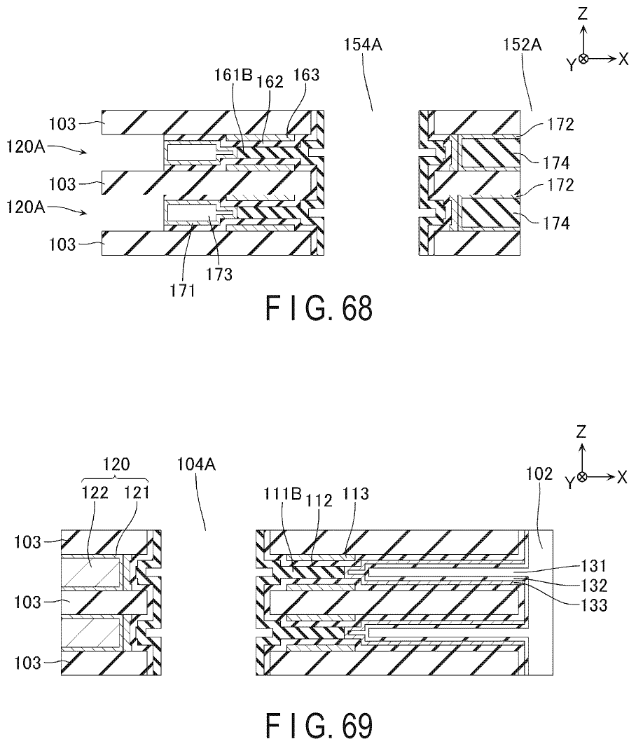

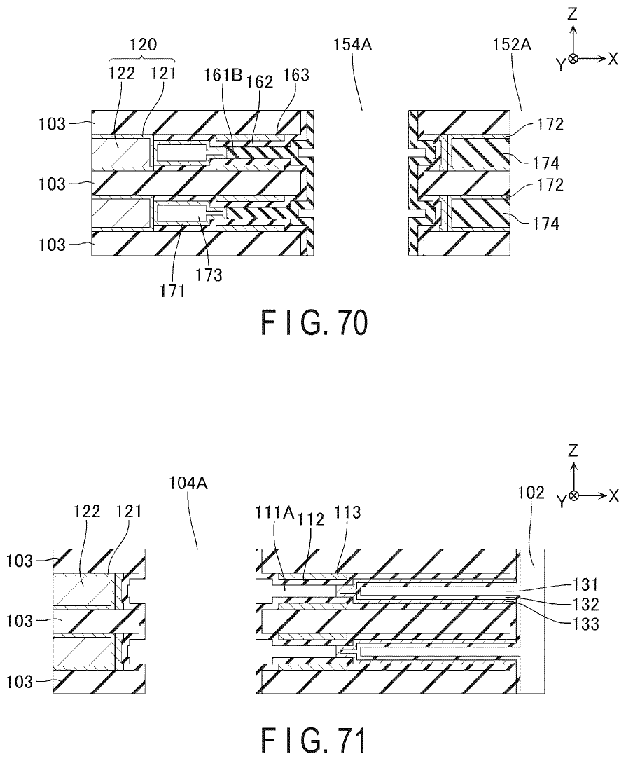

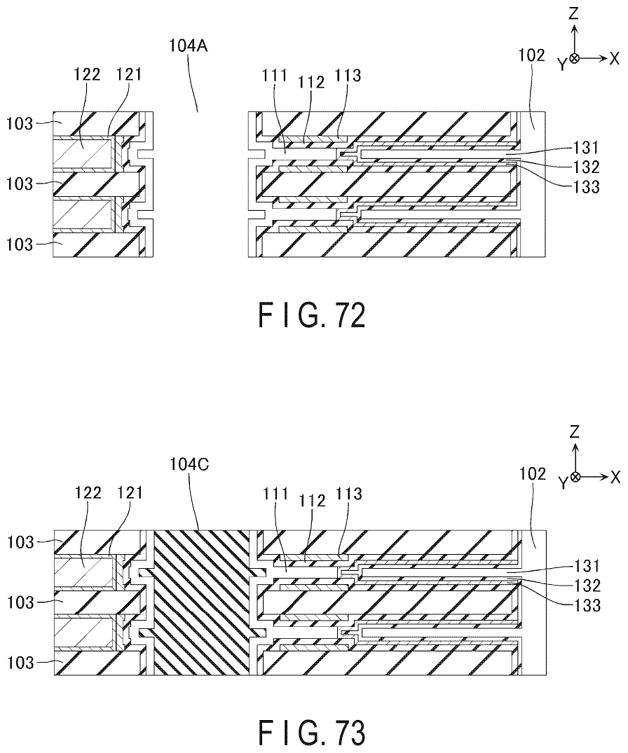

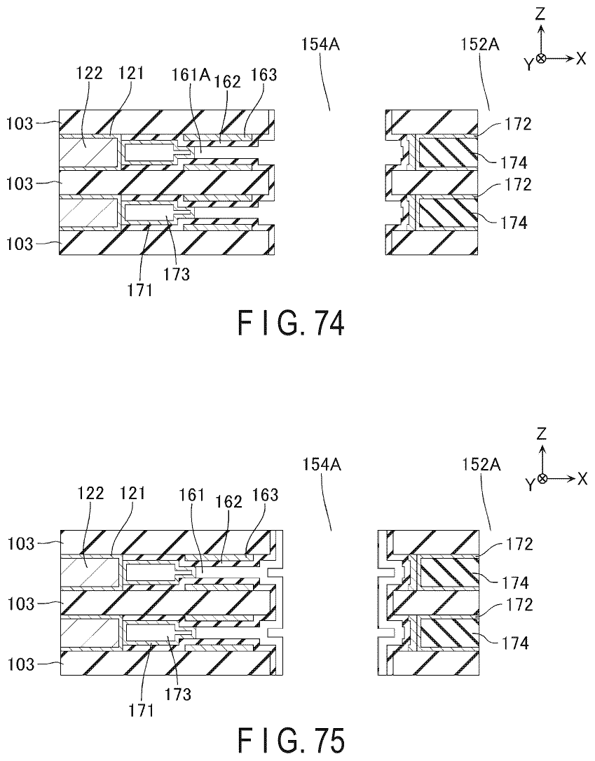

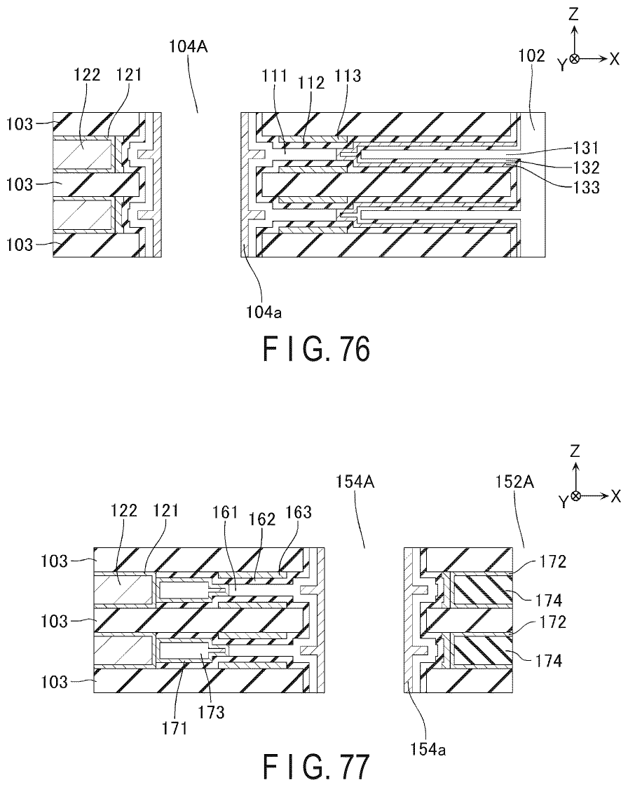

FIG. 11 to FIG. 77 are schematic cross-sectional views for describing a manufacturing method of a semiconductor memory device according to the first embodiment.

FIG. 11, FIG. 14, FIG. 16, FIG. 18, FIG. 21, FIG. 23, FIG. 25, FIG. 27, FIG. 29, FIG. 31, FIG. 33, FIG. 35, FIG. 37, FIG. 40, FIG. 41, FIG. 43, FIG. 45, FIG. 47, FIG. 49, FIG. 51, FIG. 53, FIG. 55, FIG. 57 to FIG. 60, FIG. 65, FIG. 67, FIG. 69, FIG. 71 to FIG. 73, and FIG. 76 illustrate cross sections corresponding to FIG. 7.

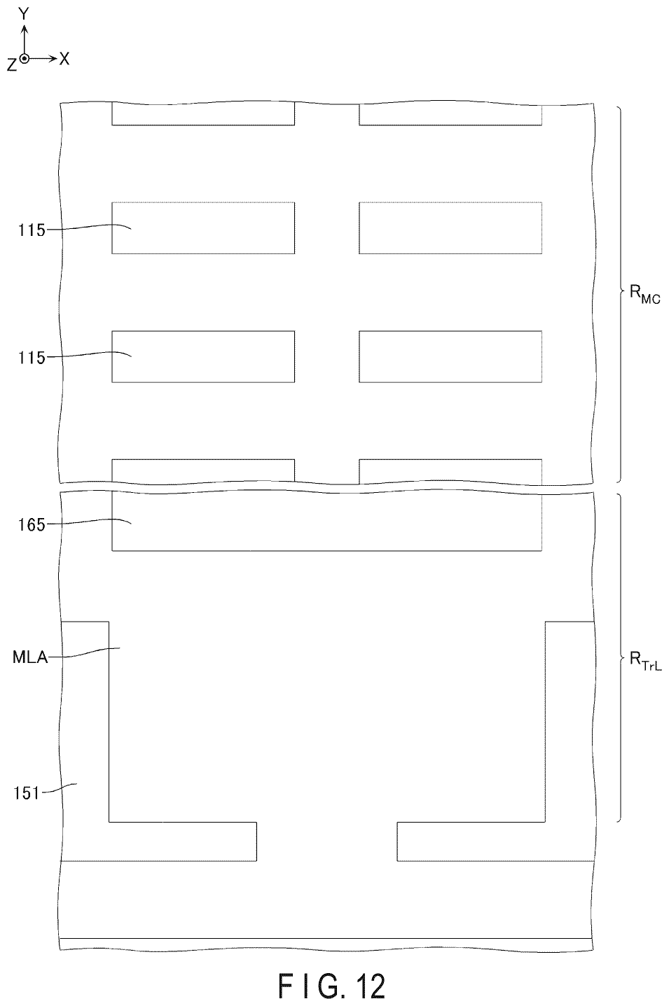

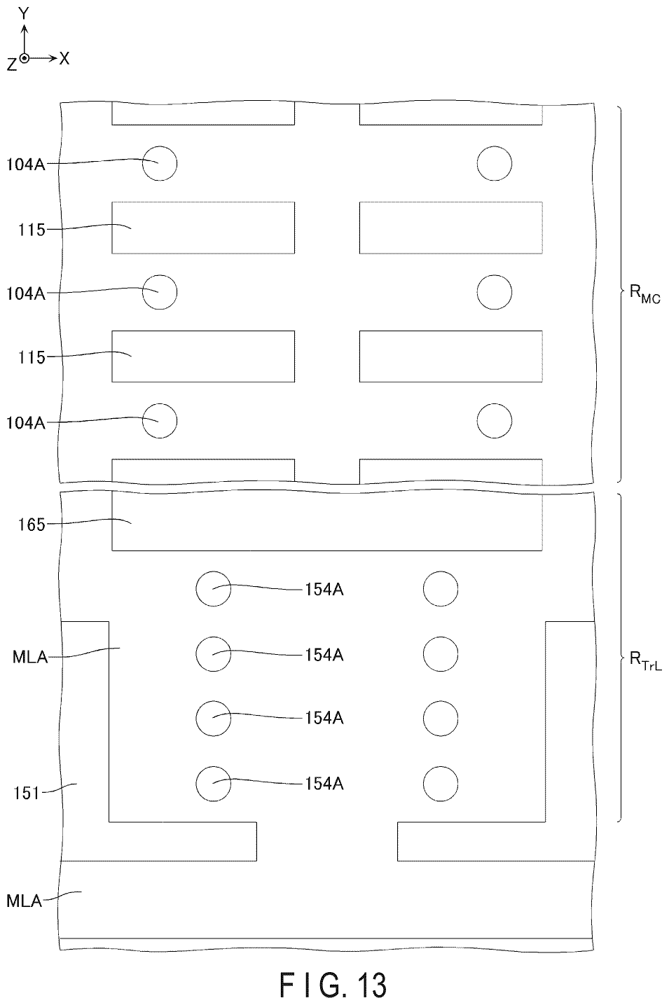

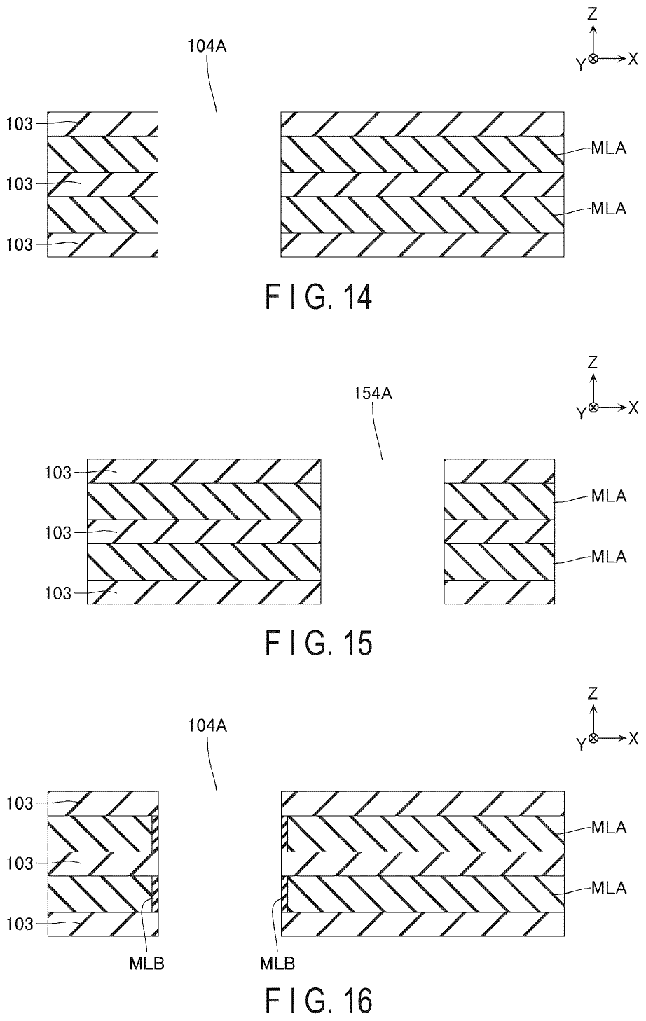

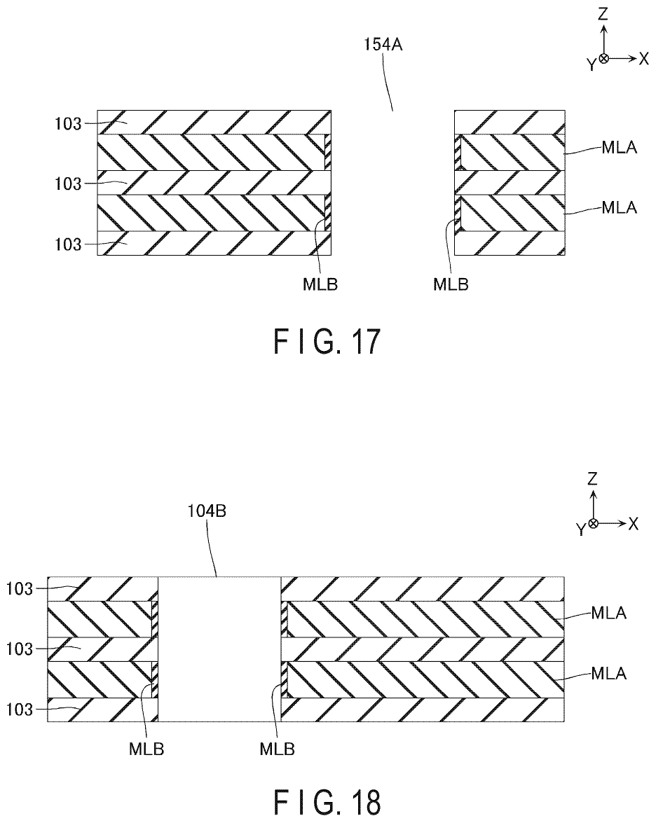

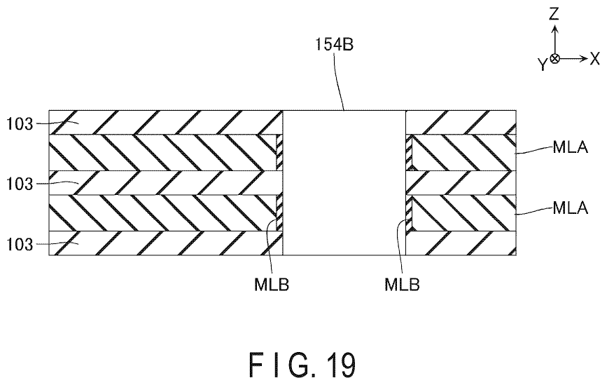

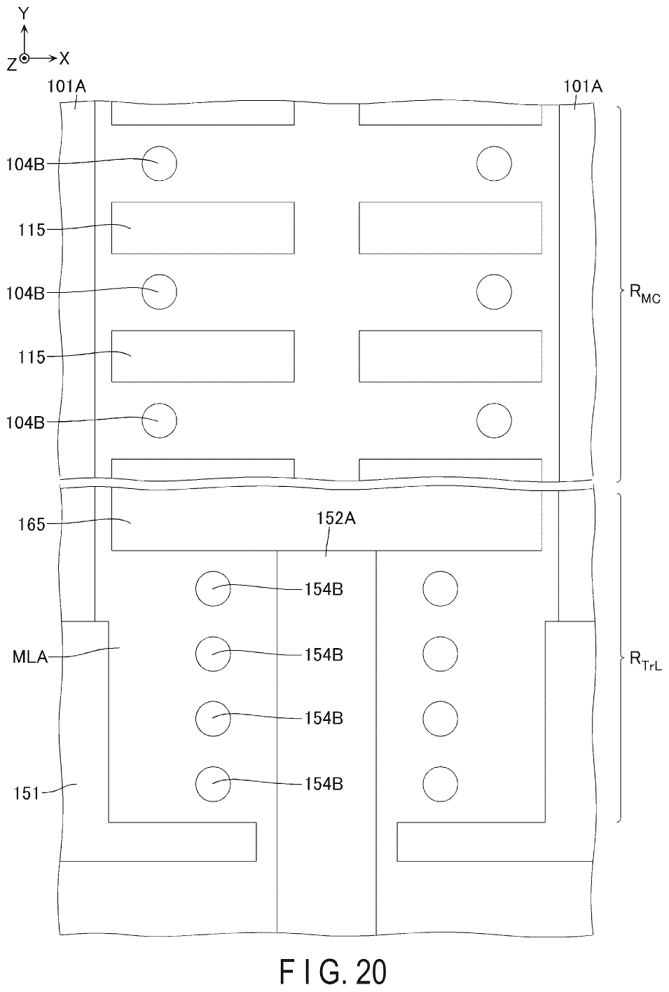

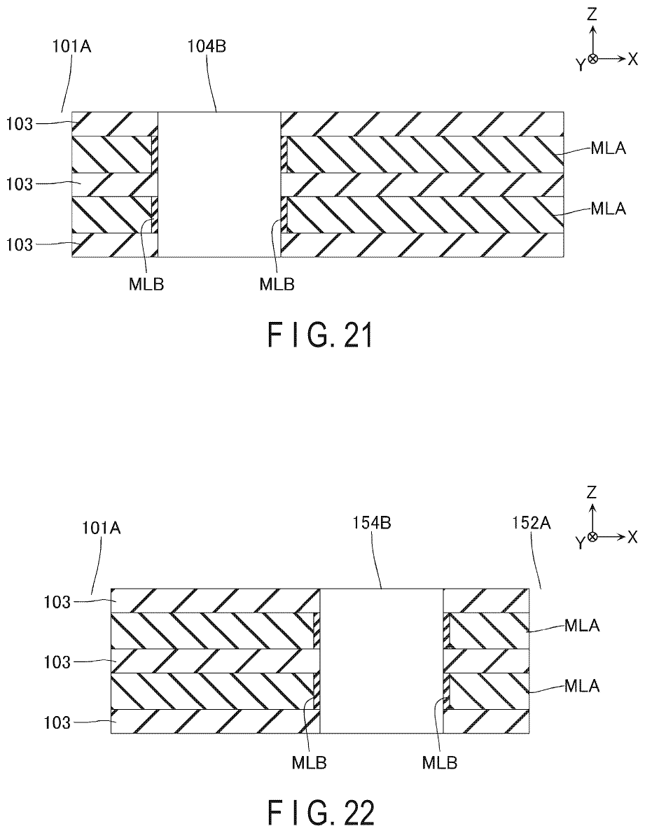

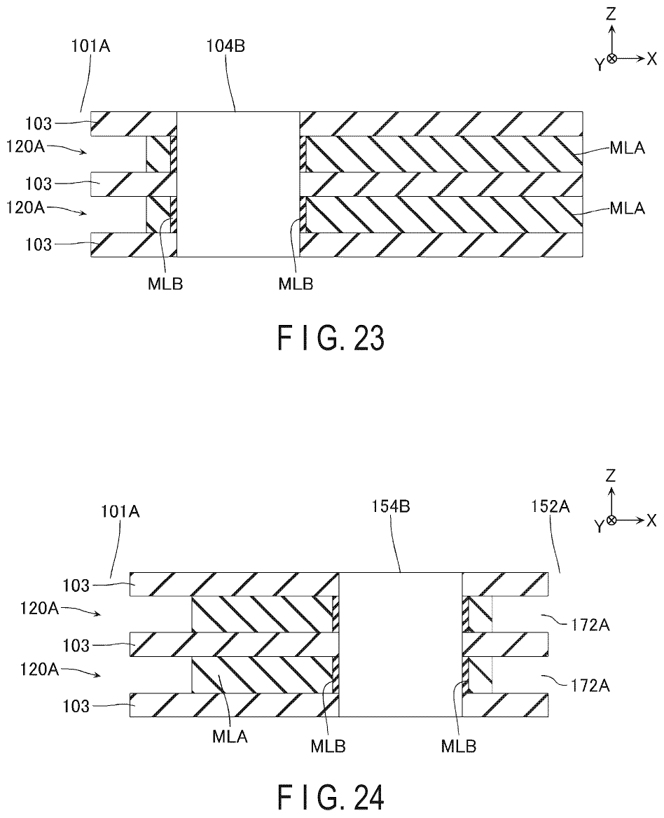

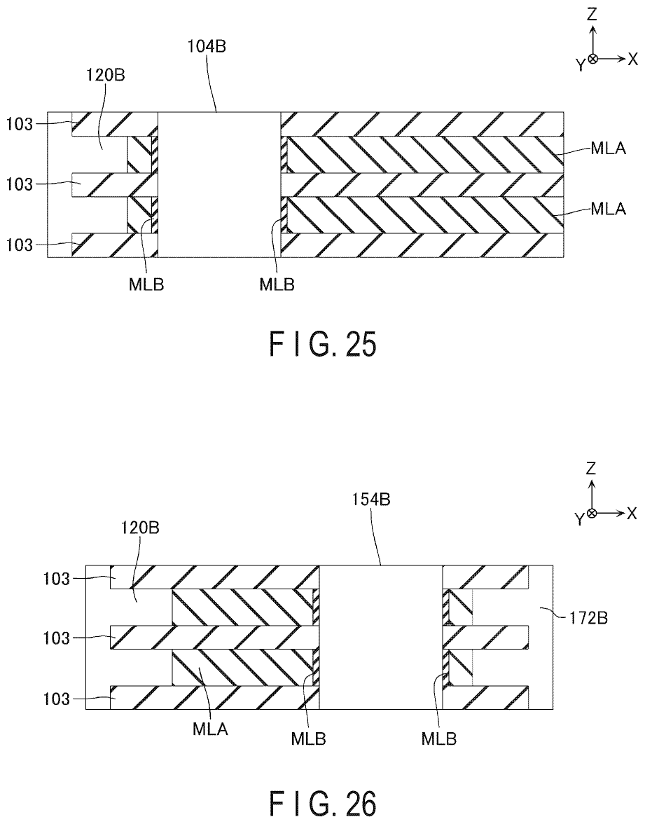

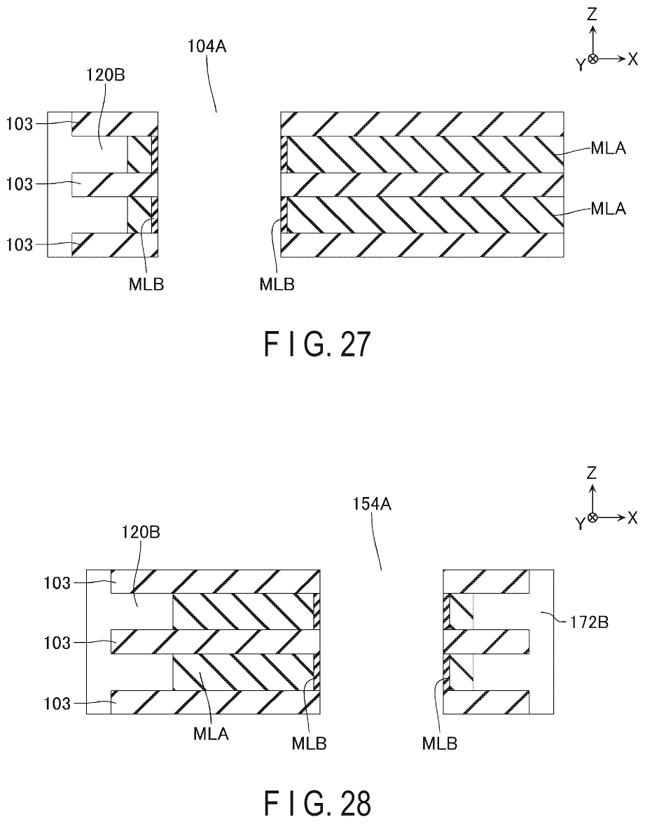

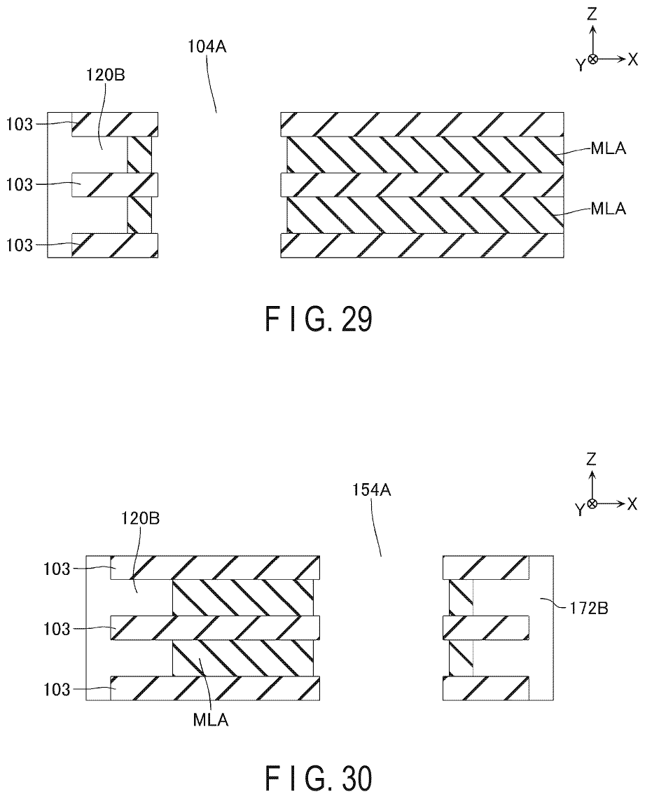

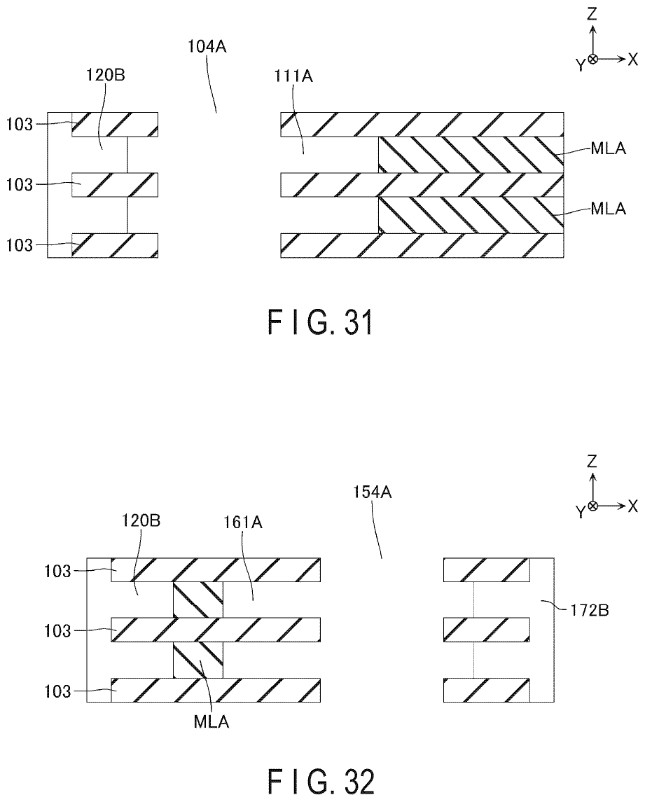

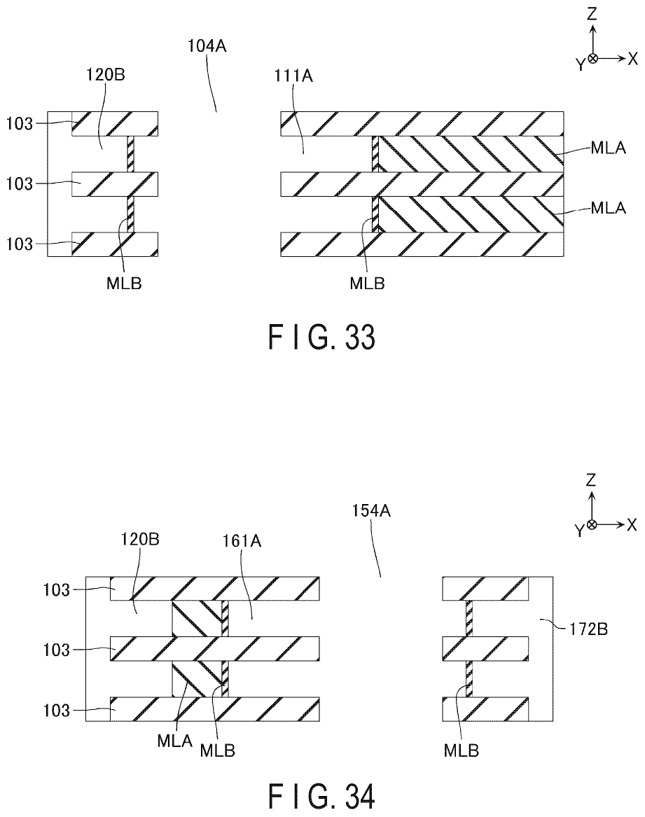

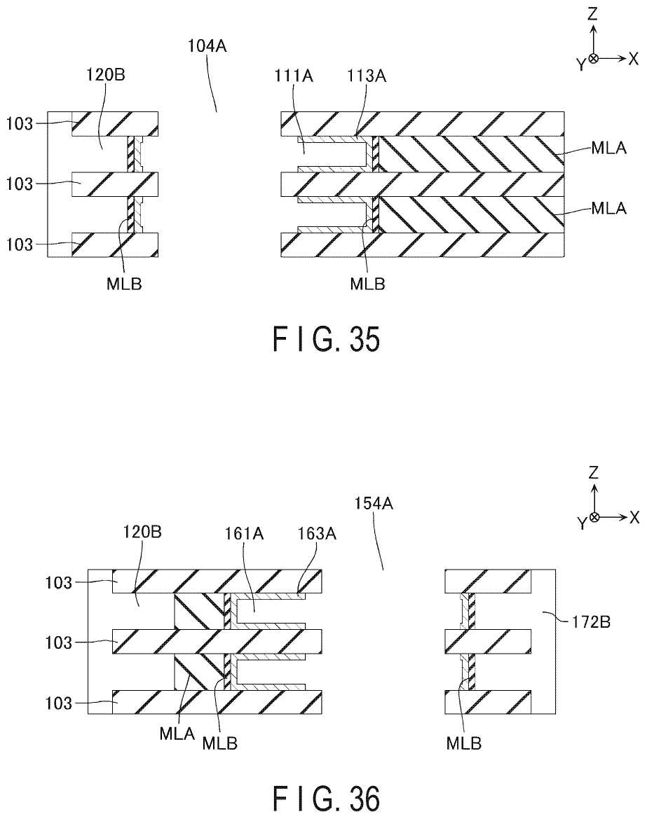

FIG. 12, FIG. 13, FIG. 20, and FIG. 39 illustrate cross-sections corresponding to FIG. 5.

FIG. 15, FIG. 17, FIG. 19, FIG. 22, FIG. 24, FIG. 26, FIG. 28, FIG. 30, FIG. 32, FIG. 34, FIG. 36, FIG. 38, FIG. 42, FIG. 44, FIG. 46, FIG. 48, FIG. 50, FIG. 52, FIG. 54, FIG. 56, FIG. 61 to FIG. 64, FIG. 66, FIG. 68, FIG. 70, FIG. 74, FIG. 75, and FIG. 77 illustrate cross sections corresponding to FIG. 9.

In the manufacturing method, as illustrated, for example, in FIG. 11, a plurality of insulating layers 103 and a plurality of sacrifice layers MLA are alternately formed. The sacrifice layer MLA contains, for example, silicon nitride (Si3N4) or the like. This step is performed by, for example, CVD (Chemical Vapor Deposition) or the like.

Next, as illustrated in, for example, FIG. 12, insulating layers 115, 151, and 165 are formed. In this step, openings are formed at positions corresponding to, for example, the insulating layers 115, 151, and 165. The openings extend in the Z direction through the plurality of insulating layers 103 and the plurality of sacrifice layers MLA that are stacked in the Z direction. This step is performed by, for example, RIE or the like. After forming the openings, the insulating layers 115, 151, and 165 are formed. This step is performed by, for example, CVD or the like.

Next, as illustrated in, for example, FIG. 13 to FIG. 15, openings 104A and 154A are formed at positions corresponding to the via wirings 104 and 154. The openings 104A and 154A extend in the Z direction as illustrated in FIG. 13 to FIG. 15, and penetrate the plurality of insulating layers 103 and the plurality of sacrifice layers MLA that are stacked in the Z direction. This step is performed by, for example, RIE or the like.

Next, as illustrated in, for example, FIG. 16 and FIG. 17, oxidation treatment is performed on surfaces of the sacrifice layers MLA exposed to the openings 104A and 154A to form oxide films MLB.

Next, as illustrated in, for example, FIG. 18 and FIG. 19, sacrifice layers 104B and 154B made from silicon (Si) or the like are formed inside the openings 104A and 154A. This step is performed by, for example, CVD or the like.

Next, as illustrated in, for example, FIG. 20 to FIG. 22, openings 101A and 152A are formed at positions corresponding to the insulating layers 101 and 152. The openings 101A and 152A extend in the Y direction and the Z direction, and penetrate the plurality of insulating layers 103 and the plurality of sacrifice layers MLA that are stacked in the Z direction to divide these configurations in the X direction. This step is performed by, for example, RIE or the like.

Next, as illustrated in, for example, FIG. 23 and FIG. 24, openings 120A and 172A are formed at positions corresponding to the conductive layers 120 and the wirings 172. A part of the upper surface and a part of the lower surface of the insulating layer 103, and a part of a side surface of the sacrifice layer MLA in the X direction are exposed to the inside of the openings 120A and 172A. In this step, a part of the sacrifice layers MLA is selectively removed via, for example, the openings 101A and 152A. This step is performed by, for example, wet etching or the like. Note that the openings 120A and 172A do not communicate with the openings 104A and 154A.

Next, as illustrated in, for example, FIG. 25 and FIG. 26, the openings 101A and 120A are filled with sacrifice layers 120B made from silicon (Si) or the like. Additionally, the openings 152A and 172A are filled with sacrifice layers 172B made from silicon (Si) or the like. This step is performed by, for example, CVD or the like.

Next, as illustrated in, for example, FIG. 27 and FIG. 28, the sacrifice layers 104B and 154B are removed. This step is performed by, for example, wet etching or the like.

Next, as illustrated in, for example, FIG. 29 and FIG. 30, the oxide films MLB are removed. This step is performed by, for example, wet etching or the like.

Next, as illustrated in, for example, FIG. 31 and FIG. 32, openings 111A and 161A are formed at positions corresponding to the semiconductor layers 111 and 161. A part of the upper surface and a part of the lower surface of the insulating layer 103, a part of a side surface of the sacrifice layer MLA in the X direction, a part of side surfaces of the insulating layers 115, 151, and 165 in the Y direction (see FIG. 20), and a part of side surfaces of the sacrifice layers 120B and 172B in the X direction are exposed to the inside of the openings 111A and 161A. In this step, a part of the sacrifice layers MLA is selectively removed via, for example, the openings 104A and 154A. This step is performed by, for example, wet etching or the like.

Next, as illustrated in, for example, FIG. 33 and FIG. 34, oxidation treatment is performed on surfaces of the sacrifice layers MLA, 120B, and 172B exposed to the openings 104A and 154A to form oxide films MLB.

Next, as illustrated in, for example, FIG. 35 and FIG. 36, conductive layers 113A and 163A are formed inside the openings 111A and 161A. In this step, a conductive film made from titanium nitride (TiN) or the like, and a sacrifice layer made from silicon (Si) or the like are formed inside, for example, the openings 104A and 111A and the openings 154A and 161A. This step is performed such that the openings 111A and 161A are filled with the sacrifice layer, and the openings 104A and 154A are not filled with the sacrifice layer. Next, a part of the sacrifice layer is removed inside the openings 104A and 154A, and a part of the conductive film (i.e., a portion formed on the side surface of the insulating layer 103) is exposed. Next, a part of the conductive film is removed, and the conductive film is divided in the Z direction to form the conductive layers 113A and 163A. Then, the sacrifice layer is removed.

Next, as illustrated in, for example, FIG. 37 and FIG. 38, the openings 104A and 154A are filled with the sacrifice layers 104B and 154B made from silicon (Si) or the like. This step is performed by, for example, CVD or the like.

Next, as illustrated in, for example, FIG. 39 and FIG. 40, an opening 102A is formed at a position corresponding to the conductive layer 102. The opening 102A extends in the Y direction and the Z direction, and penetrates the plurality of insulating layers 103 and the plurality of sacrifice layers MLA that are stacked in the Z direction and the insulating layer 115 to divide these configurations in the X direction. Additionally, an opening 153A is formed at a position corresponding to the insulating layer 153. The opening 153A extends in the Z direction, and penetrates the plurality of insulating layers 103 and the plurality of sacrifice layers MLA that are stacked in the Z direction and the insulating layer 151. This step is performed by, for example, RIE or the like.

Next, as illustrated in, for example, FIG. 41, openings 131A are formed at positions corresponding to the capacitor structures 130. Additionally, as illustrated in FIG. 42, an opening 171A is formed at a position corresponding to the wiring 171. In this step, the sacrifice layer MLA is removed via the openings 102A and 153A. This step is performed by, for example, wet etching or the like.

Next, as illustrated in, for example, FIG. 43 and FIG. 44, a part of the oxide films MLB is removed via the openings 131A and 171A. This step is performed by, for example, wet etching or the like.

Next, as illustrated in, for example, FIG. 45 and FIG. 46, the conductive layers 113 and 163 are formed. In this step, a part of the conductive layers 113A is removed via the openings 131A. Additionally, in this step, a part of the conductive layer 163A is removed via the opening 171A. This step is performed by, for example, wet etching or the like.

Next, as illustrated in, for example, FIG. 47 and FIG. 48, the sacrifice layers 104B and 154B are removed. This step is performed by, for example, wet etching or the like.

Next, as illustrated in, for example, FIG. 49, the insulating layer 112 is formed inside the openings 111A, 104A, 131A, and 102A. Additionally, as illustrated in, for example, FIG. 50, the insulating layer 162 is formed inside the openings 171A, 161A, and 154A. The insulating layers 112 and 162 are formed on upper surfaces and lower surfaces of the conductive layers 113 and 163, a part of the upper surfaces, a part of the lower surfaces, and surfaces exposed to the openings 104A and 154A of the insulating layers 103, a part of side surfaces of the sacrifice layers 120B in the X direction, and a part of side surfaces of the insulating layers 115 and 165 in the Y direction.

Next, as illustrated in, for example, FIG. 51, a sacrifice layer 111B made from silicon nitride (Si3N4) or the like is formed inside the openings 111A, 104A, 131A, and 102A. Additionally, as illustrated in, for example, FIG. 52, a sacrifice layers 161B made from silicon nitride (Si3N4) or the like is formed inside the openings 171A, 161A, and 154A. The openings 111A and 161A are filled with the sacrifice layers 111B and 161B, and the openings 102A, 104A, 131A, 154A, and 171A are not filled with the sacrifice layers 111B and 161B. This step is performed by, for example, CVD or the like. Note that, although illustration is omitted, after forming the sacrifice layers 111B and 161B, upper portions of the openings 104A and 154A are closed by an insulating layer or the like.

Next, as illustrated in, for example, FIG. 53 and FIG. 54, a part of the sacrifice layers 111B and 161B is removed via the openings 102A and 153A (see FIG. 39). This step is performed by, for example, wet etching or the like.

Next, as illustrated in, for example, FIG. 55, via the opening 102A and the openings 131A, a conductive layer 133A is formed on a side surface on one side in the X direction (i.e., a side surface on the opening 102A side) of the sacrifice layer 111B, and upper and lower surfaces, a side surface on one side in the X direction (i.e., a side surface on the opening 102A side), and a side surface in the Y direction of the insulating layer 112. Additionally, as illustrated in, for example, FIG. 56, via the opening 153A (see FIG. 39) and the opening 171A, a conductive layer 171B is formed on a side surface on one side in the X direction (i.e., a side surface on the opening 171A side) of the sacrifice layer 161B, and upper and lower surfaces, a side surface on one side in the X direction (i.e., a side surface on the opening 171A side), and a side surface in the Y direction of the insulating layer 162. This step is performed by, for example, ALD (Atomic Layer Deposition) or the like.

Next, as illustrated in, for example, FIG. 57, sacrifice layers 131B made from silicon (Si) or the like are formed inside the opening 102A. The openings 131A are filled with the sacrifice layers 131B, and the opening 102A is not filled with the sacrifice layer 131B. Additionally, although illustration is omitted, a sacrifice layer made from silicon (Si) or the like is formed inside the opening 171A. The opening 171A is filled with the sacrifice layer, and the opening 153A (see FIG. 39) is not filled with the sacrifice layer. This step is performed by, for example, CVD or the like.

Additionally, as illustrated in, for example, FIG. 58, the conductive layers 133 are formed. In this step, for example, portions of the sacrifice layers 131B provided on side surfaces of the insulating layer 115 and the insulating layer 103 in the X direction are removed to expose a part of the conductive layer 133A. Additionally, portions of the conductive layer 133A provided on side surfaces of the insulating layer 115 and the insulating layer 103 in the X direction are removed, and the conductive layer 133A is divided in the Y direction and the Z direction. This step is performed by, for example, wet etching or the like. Note that, although illustration is omitted, in this step, the conductive layer 171B is divided in the Z direction, and thus the wiring 171 is formed. After forming the conductive layers 133, an upper portion of the opening 153A (see FIG. 39) is closed by an insulating layer or the like.

Next, as illustrated in, for example, FIG. 59, the sacrifice layers 131B are removed. This step is performed by, for example, wet etching or the like.

Next, as illustrated in, for example, FIG. 60, via the openings 131A and the opening 102A, the insulating layer 132 and the conductive layer 131 are formed on the upper surface, the lower surface, the side surface on one side in the X direction (i.e., the side surface on the opening 102A side), and both side surfaces in the Y direction of the conductive layer 133, and the side surfaces of the insulating layer 115 and the insulating layer 103 in the X direction. This step is performed by, for example, CVD or the like.

Next, as illustrated in, for example, FIG. 61, via the opening 153A (see FIG. 39) and the opening 171A, the semiconductor layer 173 is formed on an upper surface, a lower surface, and side surfaces in the X direction and the Y direction of the wiring 171. This step is performed by, for example, CVD or the like.

Next, as illustrated in, for example, FIG. 61, the sacrifice layers 172B are removed. This step is performed by, for example, wet etching or the like.

Next, as illustrated in, for example, FIG. 62, the oxide films MLB are removed. This step is performed by, for example, wet etching or the like.

Next, as illustrated in, for example, FIG. 63, the wiring 172 is formed. This step is performed in a manner similar to the steps described with reference to FIG. 55 to FIG. 59.

Next, as illustrated in, for example, FIG. 64, the insulating layers 174 are formed. This step is performed with, for example, a method such as CVD.

Next, as illustrated in, for example, FIG. 65 and FIG. 66, the sacrifice layers 120B are removed. This step is performed by, for example, wet etching or the like.

Next, as illustrated in, for example, FIG. 67 and FIG. 68, the oxide films MLB and a part of the insulating layers 162 (i.e., the portions exposed to the opening 120A) are removed. This step is performed by, for example, wet etching or the like.

Next, as illustrated in, for example, FIG. 69 and FIG. 70, the conductive layers 120 are formed. This step is performed with, for example, a method such as CVD.

Next, as illustrated in, for example, FIG. 71, the sacrifice layers 111B are removed inside the opening 104A. This step is performed by, for example, wet etching or the like.

Next, as illustrated in, for example, FIG. 72, the semiconductor layers 111 are formed inside the openings 111A and 104A. The openings 111A are filled with the semiconductor layers 111. On the other hand, the opening 104A is not filled with the semiconductor layers 111. This step is performed by, for example, ALD or the like.

Next, as illustrated in, for example, FIG. 73, a resist 104C is formed inside the opening 104A.

Next, as illustrated in, for example, FIG. 74, the sacrifice layers 161B are removed inside the opening 154A. This step is performed by, for example, wet etching or the like.

Next, as illustrated in, for example, FIG. 75, the semiconductor layers 161 are formed inside the openings 161A and 154A. The openings 161A are filled with the semiconductor layers 161. On the other hand, the opening 154A is not filled with the semiconductor layers 161. This step is performed by, for example, ALD or the like.

Next, as illustrated in, for example, FIG. 76, the resist 104C is removed.

Next, as illustrated in, for example, FIG. 76, the conductive oxide film 104a is formed inside the opening 104A. Additionally, as illustrated in, for example, FIG. 77, the conductive oxide film 154a is formed inside the opening 154A. This step is performed by, for example, ALD or the like.

Then, as illustrated in, for example, FIG. 7, the barrier conductive film 104b and the conductive member 104c are formed inside the opening 104A. Additionally, as illustrated in, for example, FIG. 9, the barrier conductive film 154b and the conductive member 154c are formed inside the opening 154A. This step is performed with, for example, a method such as CVD. Accordingly, the structure described with reference to FIG. 4 to FIG. 10 is formed.

### Second Embodiment

In the first embodiment, the composition ratio of the materials included in the semiconductor layer 111 in the transistor layer TL is the same as the composition ratio of the materials included in the semiconductor layer 111 in the memory layer ML. However, such a configuration is merely exemplification, and the specific configuration of the transistor layer TL can be appropriately adjusted. For example, the composition ratio of the materials included in the semiconductor layer 111 in the transistor layer TL may be different from the composition ratio of the materials included in the semiconductor layer 111 in the memory layer ML. Accordingly, it is also possible to set the threshold voltage of the transistor TrB to a lower value (for example, a value lower than the threshold voltage of the transistor TrC). Hereinafter, such a configuration is exemplified as a semiconductor memory device according to a second embodiment.

### [Configuration]

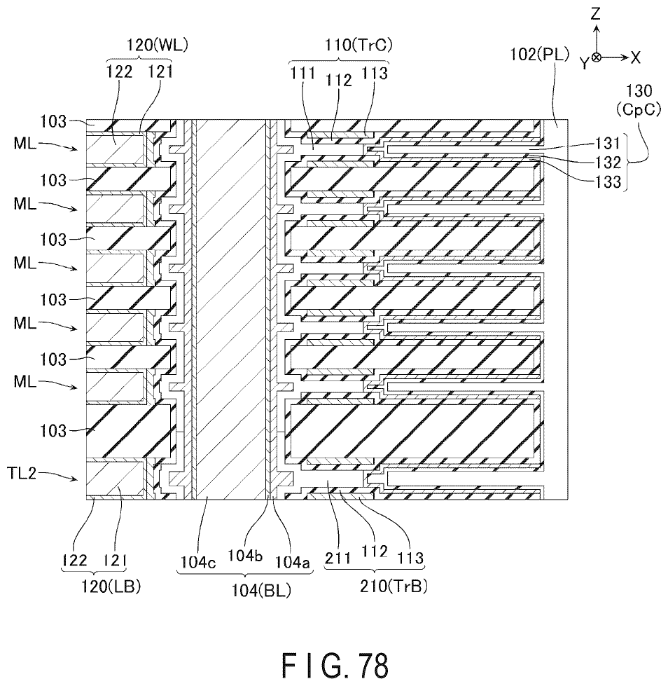

FIG. 78 is a schematic cross-sectional view illustrating the configuration of a part of the semiconductor memory device according to the second embodiment. In the following description, the same numerals are assigned to elements similar to those in the first embodiment, and a description thereof is not repeated.

The semiconductor memory device according to the second embodiment is formed basically similarly to the semiconductor memory device according to the first embodiment. However, the semiconductor memory device according to the second embodiment includes a transistor layer TL2 instead of the transistor layer TL.

The transistor layer TL2 is formed basically similarly to the transistor layer TL. However, the transistor layer TL2 includes a transistor structure 210 instead of the transistor structure 110.

The transistor structure 210 is formed basically similarly to the transistor structure 110. However, the transistor structure 210 includes a semiconductor layer 211 instead of the semiconductor layer 111.

The semiconductor layer 211 is formed basically similarly to the semiconductor layer 111. However, the concentration of indium in the semiconductor layer 211 is higher than the concentration of indium in the semiconductor layer 111. Additionally, the concentration of gallium in the semiconductor layer 211 is equal to or less than the concentration of gallium in the semiconductor layer 111. Accordingly, the threshold voltage of the transistor TrB (see FIG. 1) becomes lower than the threshold voltage of the transistor TrC.

### [Manufacturing Method]

Next, a manufacturing method of the semiconductor memory device according to the second embodiment will be described. Here, an example is illustrated in which the semiconductor memory device according to the second embodiment is manufactured by forming the configurations of the memory cell array MCA and the like, and the semiconductor substrate Sub (see FIG. 4) and the aforementioned control circuit on separate wafers, and bonding these two wafers to each other.

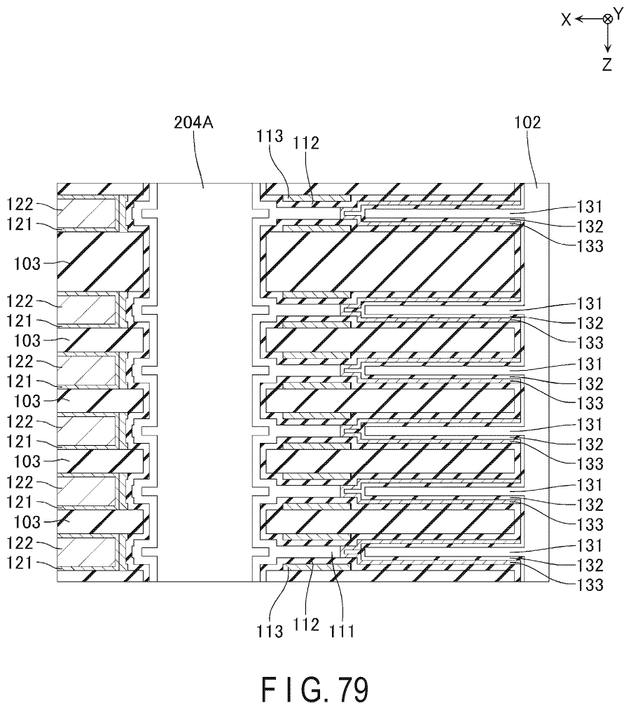

FIG. 79 to FIG. 84 are schematic cross-sectional views for describing the manufacturing method of the semiconductor memory device according to the second embodiment.

When manufacturing the semiconductor memory device according to the second embodiment, the steps described with reference to, for example, FIG. 11 to FIG. 72 are performed. However, these steps are performed such that, on the upper side of a wafer that is not illustrated, the structure located on the upper side of the memory cell array MCA is provided on the lower side, and the structure located on the lower side is provided on the upper side. For example, in the step described with reference to FIG. 11, first, the plurality of sacrifice layers MLA corresponding to the memory layers ML are formed, and then, the sacrifice layer MLA corresponding to the transistor layer TL is formed.

Next, as illustrated in FIG. 79, a sacrifice layer 204A is formed inside the opening 104A. This step is performed by, for example, CVD or the like.

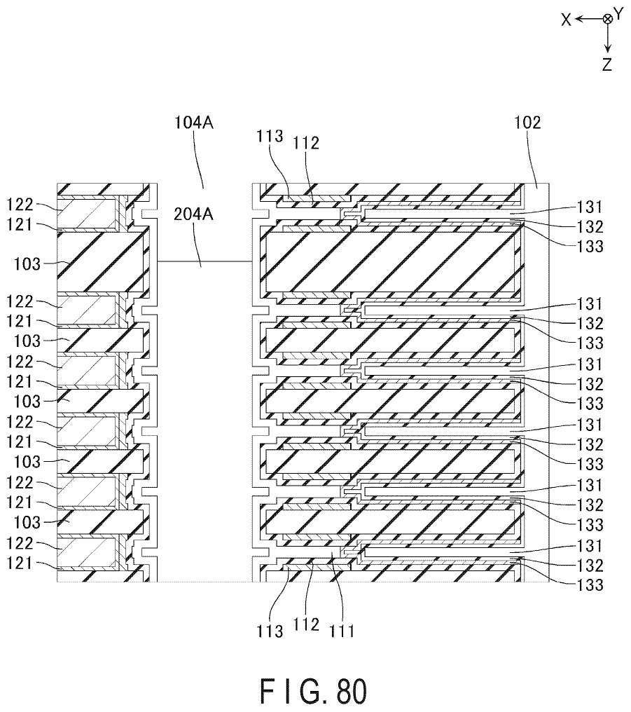

Next, as illustrated in FIG. 80, a part of the sacrifice layer 204A is removed, and a portion of the semiconductor layer 111 provided at the position corresponding to the transistor layer TL is exposed to the inside of the opening 104A. This step is performed by, for example, wet etching or the like.

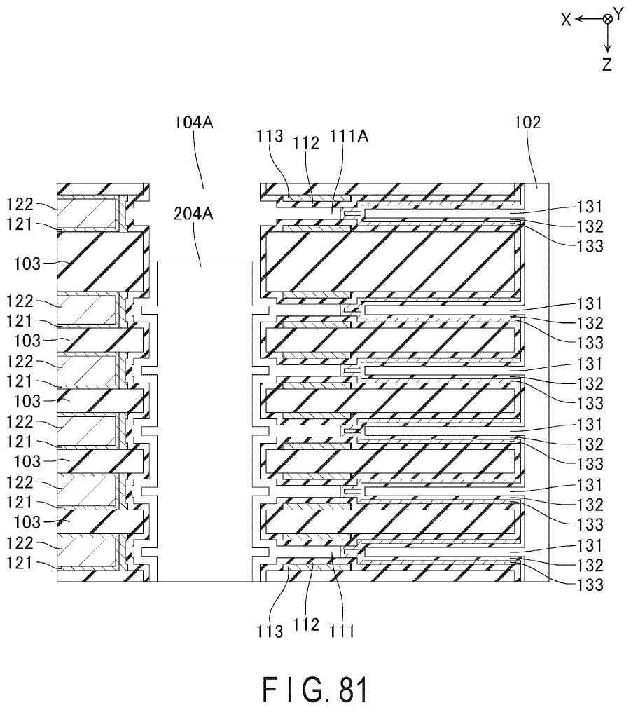

Next, as illustrated in FIG. 81, a portion of the semiconductor layer 111 provided at the position corresponding to the transistor layer TL is removed. This step is performed by, for example, wet etching or the like.

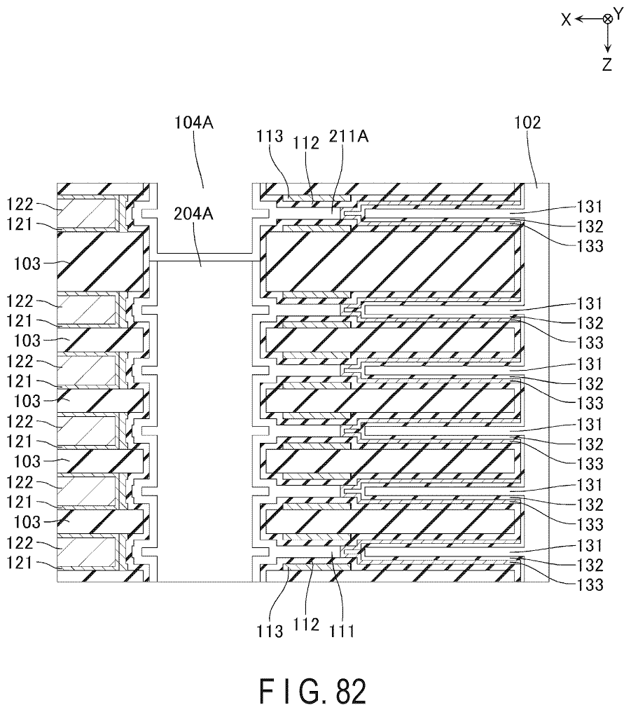

Next, as illustrated in FIG. 82, a semiconductor layer 211A is formed inside the openings 111A and 104A and on an upper surface of the sacrifice layer 204A. The opening 111A is filled with the semiconductor layer 211A. On the other hand, the opening 104A is not filled with the semiconductor layer 211A. This step is performed by, for example, ALD or the like.

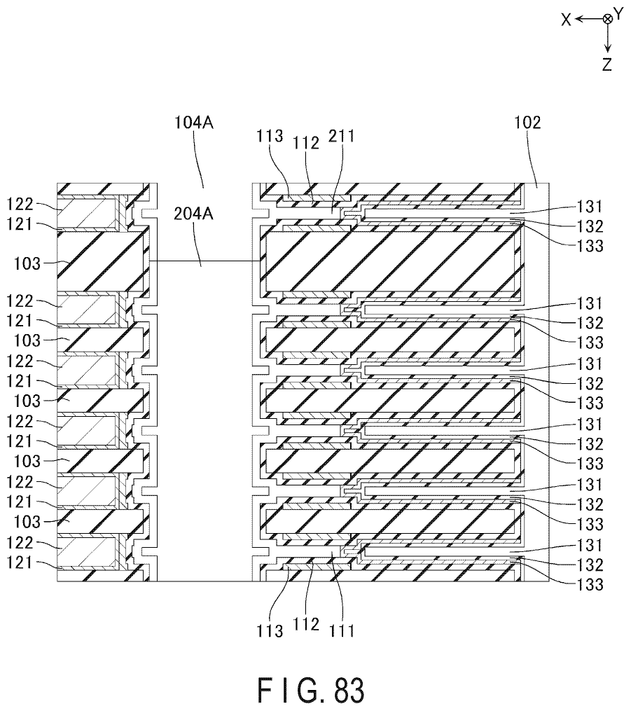

Next, as illustrated in FIG. 83, a portion of the semiconductor layer 211A provided on the upper surface of the sacrifice layer 204A is removed. Accordingly, the semiconductor layer 211 is formed. This step is performed by, for example, RIE or the like.

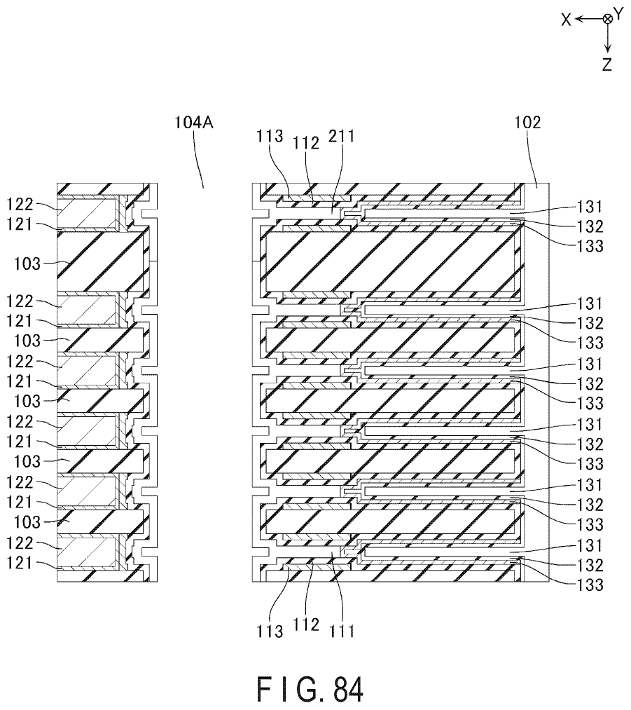

Next, as illustrated in FIG. 84, the sacrifice layer 204A is removed. This step is performed by, for example, wet etching or the like.

Next, the memory cell array MCA of the semiconductor memory device according to the second embodiment is formed by performing the steps after the step described with reference to FIG. 72 of the manufacturing method according to the first embodiment. Additionally, the wafer on which the memory cell array MCA is formed is turned upside down, and is bonded to the wafer on which the semiconductor substrate Sub (see FIG. 4) and the aforementioned control circuit are formed. In this manner, the semiconductor memory device according to the second embodiment is manufactured.

### Third Embodiment

In the first embodiment, as described with reference to FIG. 71 to FIG. 75, the semiconductor layer 111 and the semiconductor layer 161, which have different compositions from each other, are deposited in separate steps. Additionally, in the second embodiment, as described with reference to FIG. 79 to FIG. 84, the semiconductor layer 111 and the semiconductor layer 211, which have different compositions from each other, are deposited in separate steps. However, such methods are merely exemplification, and the method of depositing the semiconductor layers having different compositions from each other can be appropriately adjusted; for example, it is also possible to collectively deposit them. Accordingly, it is possible to reduce the number of manufacturing steps. Hereinafter, such a configuration is exemplified as a semiconductor memory device according to a third embodiment.

### [Configuration]

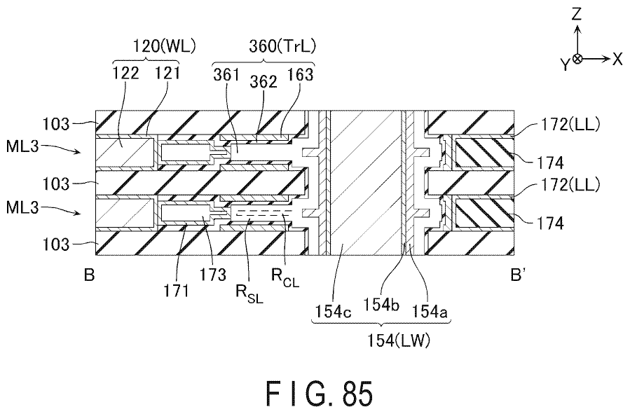

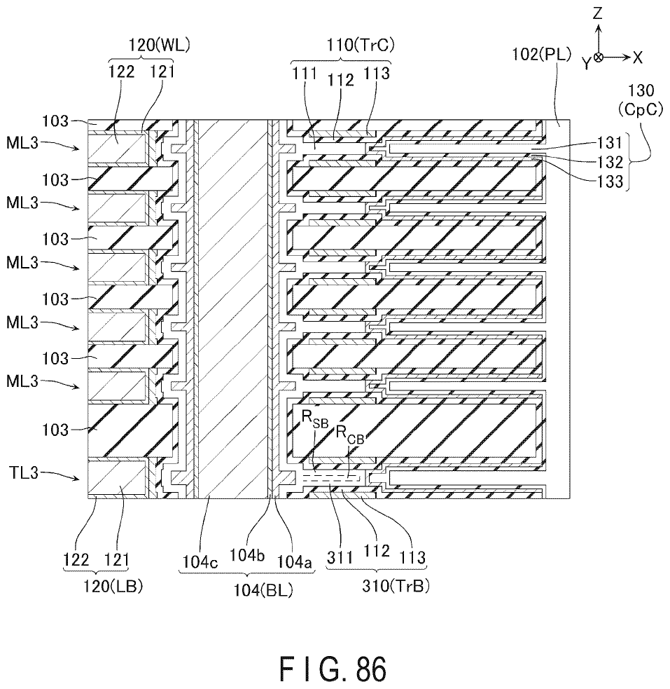

FIG. 85 and FIG. 86 are schematic cross-sectional views illustrating the configuration of a part of the semiconductor memory device according to the third embodiment. In the following description, the same numerals are assigned to elements similar to those in the second embodiment, and a description thereof is not repeated.

The semiconductor memory device according to the third embodiment is formed basically similarly to the semiconductor memory device according to the second embodiment.

However, the semiconductor memory device according to the third embodiment includes memory layers ML3 and a transistor layer TL3, instead of the memory layers ML and the transistor layer TL2.

The memory layers ML3 and the transistor layer TL3 are formed basically similarly to the memory layers ML and the transistor layer TL2. However, the memory layer ML3 includes a transistor structure 360 instead of the transistor structure 160. Additionally, the transistor layer TL3 includes a transistor structure 310 instead of the transistor structure 210.

The transistor structure 360 is formed basically similarly to the transistor structure 160. However, the transistor structure 360 includes a semiconductor layer 361 and an insulating layer 362, instead of the semiconductor layer 161 and the insulating layer 162.

The semiconductor layer 361 is formed basically similarly to the semiconductor layer 161. However, the length of the semiconductor layer 161 in the Z direction is equal to the length of the semiconductor layer 111 in the Z direction. On the other hand, the length of the semiconductor layer 361 in the Z direction is larger than the length of the semiconductor layer 111 in the Z direction.

Additionally, when focusing on an area RSL of the semiconductor layer 361 in the vicinity of an upper surface and a lower surface thereof and the wiring 171, and an area RCL of the semiconductor layer 361 in the vicinity of a center position in the Z direction, the concentration of indium in the area RCL may be higher than the concentration of indium in the area RSL. Additionally, the concentration of gallium in the area RCL may be equal to or less than the concentration of gallium in the area RSL. Additionally, the concentrations of indium and gallium may be equal in the area RSL and the area RCL.

The insulating layer 362 is formed basically similarly to the insulating layer 162. However, the thickness of the insulating layer 162 (i.e., the distance between the semiconductor layer 161 and the conductive layer 163) is equal to the thickness of the semiconductor layer 111 (i.e., the distance between the semiconductor layer 111 and the conductive layer 113). On the other hand, the thickness of the insulating layer 362 (i.e., the distance between the semiconductor layer 361 and the conductive layer 163) is smaller than the thickness of the semiconductor layer 111.

The transistor structure 310 is formed basically similarly to the transistor structure 210. However, the transistor structure 310 includes a semiconductor layer 311 instead of the semiconductor layer 211.

The semiconductor layer 311 is formed basically similarly to the semiconductor layer 211. However, when focusing on an area RSB of the semiconductor layer 311 in the vicinity of an upper surface and a lower surface thereof and the conductive layer 133, and an area RCB of the semiconductor layer 311 in the vicinity of a center position in the Z direction, the concentration of indium in the area RCB may be higher than the concentration of indium in the area RSB. Additionally, the concentration of gallium in the area RCB may be equal to or less than the concentration of gallium in the area RSB. Additionally, the concentrations of indium and gallium may be equal in the area RSB and the area RCB.

### [Manufacturing Method]

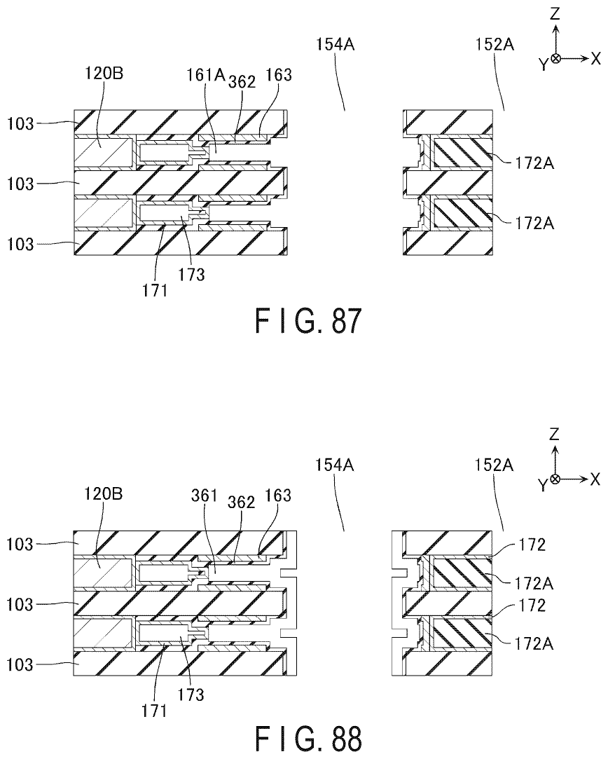

FIG. 87 and FIG. 88 are schematic cross-sectional views for describing the manufacturing method of the semiconductor memory device according to the third embodiment.

When manufacturing the semiconductor memory device according to the third embodiment, the steps described with reference to, for example, FIG. 11 to FIG. 70 are performed.

Next, as illustrated in FIG. 71, the sacrifice layers 111B are removed inside the opening 104A. Additionally, as illustrated in FIG. 74, the sacrifice layers 161B are removed inside the opening 154A. This step is performed by, for example, wet etching or the like. Although illustration is omitted, after removing the sacrifice layers 111B and 161B, the upper portion of the opening 104A is closed by an insulating layer or the like.

Next, as illustrated in FIG. 87, a part of the insulating layers 112 is removed inside the opening 154A, and the thicknesses of the insulating layers 112 are reduced to form the insulating layers 362. This step is performed by, for example, wet etching or the like.

Next, after removing the insulating layer or the like in the upper portion of the opening 104A, as illustrated in, for example, FIG. 72, the semiconductor layers 111 are formed inside the openings 111A and 104A. The openings 111A are filled with the semiconductor layers 111. On the other hand, the opening 104A is not filled with the semiconductor layers 111. Additionally, as illustrated in, for example, FIG. 88, the semiconductor layers 361 are formed inside the openings 161A and 154A. The openings 161A are filled with the semiconductor layers 361. On the other hand, the opening 154A is not filled with the semiconductor layers 361. This step is performed by, for example, ALD or the like.

In this step, the concentration of indium is continuously or gradually increased from the start of deposition to the end of deposition. Additionally, the concentration of gallium may be continuously or gradually decreased.

Here, at the timing after execution of the step described with reference to FIG. 87, the length of the opening 161A in the Z direction is larger than the length of the opening 111A (see FIG. 71) in the Z direction. Accordingly, when deposition is performed on the inside of the openings 111A and 161A at the same time, the openings 111A are filled first. Accordingly, after the openings 111A are filled, by increasing the concentration of indium and maintaining or decreasing the concentration of gallium in the semiconductor layers 361, it is possible to form the areas RCL as mentioned above inside the semiconductor layers 361.

Additionally, in the example of FIG. 86, the length in the Z direction of the semiconductor layer 111 in the transistor layer TL is larger than the length in the Z direction of the semiconductor layers 111 in the memory layers ML. When manufacturing such a configuration, at the timing after execution of the step described with reference to FIG. 87, the length in the Z direction of the opening 111A in the transistor layer TL3 becomes larger than the length in the Z direction of the openings 111A in the memory layers ML3. Accordingly, after the openings 111A in the memory layers ML3 are filled, by increasing the concentration of indium and decreasing the concentration of gallium in the semiconductor layer 311, it is possible to form the area RCB as mentioned above inside the semiconductor layer 311.

### Fourth Embodiment

In the first embodiment to the third embodiment, the semiconductor layers 111, 161 and the like contain an oxide semiconductor. However, such a configuration is merely exemplification, and the specific configuration can be appropriately adjusted. For example, the semiconductor layers 111, 161 and the like may contain materials other than an oxide semiconductor, such as silicon (Si) and germanium (Ge). Hereinafter, such a configuration is exemplified as a semiconductor memory device according to a fourth embodiment.

### [Configuration]

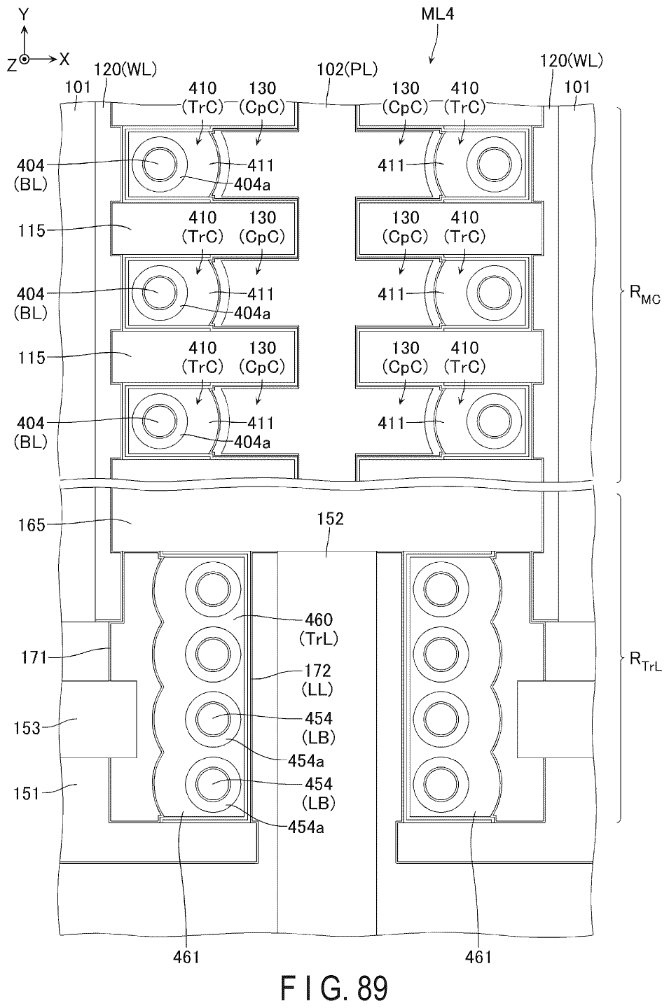

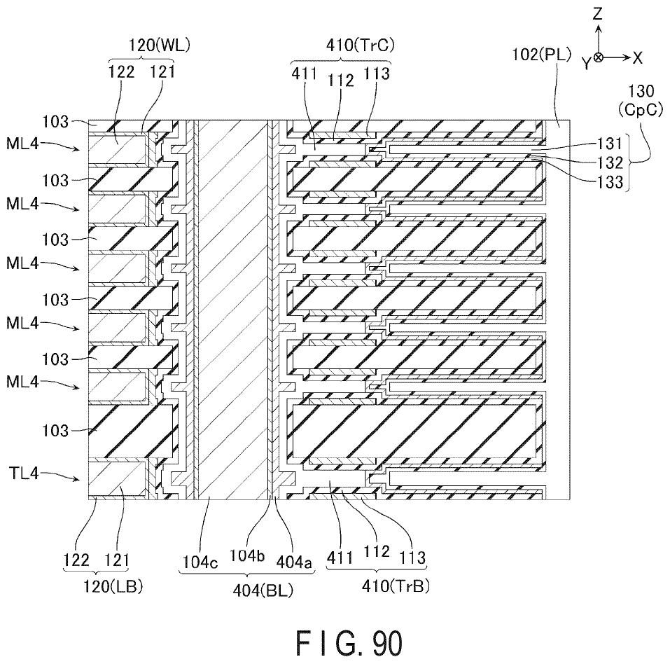

FIG. 89 and FIG. 90 are schematic cross-sectional views illustrating the configuration of a part of the semiconductor memory device according to the fourth embodiment. In the following description, the same numerals are assigned to elements similar to those in the first embodiment, and a description thereof is not repeated.

The semiconductor memory device according to the fourth embodiment is formed basically similarly to the semiconductor memory device according to the first embodiment.

However, the semiconductor memory device according to the fourth embodiment includes via wirings 404 and 454, memory layers ML4, and a transistor layer TL4, instead of the via wirings 104 and 154, the memory layers ML, and the transistor layer TL.

The via wirings 404 and 454 are formed basically similarly to the via wirings 104 and 154. However, the via wirings 404 and 454 include semiconductor films 404a and 454a, instead of the conductive oxide film 104a (see FIG. 7) and the conductive oxide film 154a (see FIG. 9). The semiconductor films 404a and 454a are formed basically similarly to the conductive oxide films 104a and 154a. However, the semiconductor films 404a and 454a include silicon (Si) as the main component, and contain an N-type impurity such as phosphorus (P) or arsenic (As). Note that, in this specification, “the main component” means the element contained in the largest amount. For example, the element contained in the largest amount in the semiconductor films 404a and 454a is silicon (Si).

The memory layers ML4 and the transistor layer TL4 are formed basically similarly to the memory layers ML and the transistor layer TL. However, the memory layers ML4 and the transistor layer TL4 include transistor structures 410 and 460, instead of the transistor structures 110 and 160, respectively.

The transistor structure 410 is formed basically similarly to the transistor structure 110. However, the transistor structure 410 includes a semiconductor layer 411 instead of the semiconductor layer 111.

The semiconductor layer 411 is formed basically similarly to the semiconductor layer 111. However, the semiconductor layer 411 includes silicon (Si) as the main component, and contains a P-type impurity such as boron (B).

Note that, in the fourth embodiment, the conductive layer 133 includes silicon (Si) as the main component, and contains an N-type impurity such as phosphorus (P) or arsenic (As).

The transistor structure 460 is formed basically similarly to the transistor structure 160. However, the transistor structure 460 includes a semiconductor layer 461 instead of the semiconductor layer 161.

The semiconductor layer 461 is formed basically similarly to the semiconductor layer 161. However, the semiconductor layer 461 includes silicon (Si) as the main component, and contains a P-type impurity such as boron (B).

Additionally, in the fourth embodiment, the wiring 171 includes silicon (Si) as the main component, and contains an N-type impurity such as phosphorus (P) or arsenic (As).

Here, the concentration of the P-type impurity in the semiconductor layer 461 is lower than the concentration of the P-type impurity in the semiconductor layer 411. Accordingly, the threshold voltage of the transistor TrL (see FIG. 1) becomes lower than the threshold voltage of the transistor TrC.

### Fifth Embodiment

In the first embodiment to the third embodiment, similar to the semiconductor layer 111 that functions as the channel area of the transistor TrC, the semiconductor layer 161 and the like that function as the channel area of the transistor TrL, and the semiconductor layer 111 and the like that function as the channel area of the transistor TrB contain an oxide semiconductor. Additionally, in the fourth embodiment, similar to the semiconductor layer 411 that functions as the channel area of the transistor TrC, the semiconductor layer 461 that functions as the channel area of the transistor TrL, and the semiconductor layer 411 that functions as the channel area of the transistor TrB includes silicon as the main component, and contain a P-type impurity such as boron (B).

However, such a configuration is merely exemplification, and the specific configuration can be appropriately adjusted. For example, the semiconductor layer 161 and the like that function as the channel area of the transistor TrL, and the semiconductor layer 111 and the like that function as the channel area of the transistor TrB may contain a different material from the semiconductor layer 111 and the like that function as the channel area of the transistor TrC. For example, one to three of the semiconductor layer 111 and the like in the memory layer ML, the semiconductor layer 161 and the like in the memory layer ML, the semiconductor layer 111 and the like in the transistor layer TL, and the semiconductor layer 161 and the like in the transistor layer TL may include an oxide semiconductor, and the remaining three to one may contain materials other than an oxide semiconductor, such as silicon and germanium. Hereinafter, such a configuration is exemplified as a semiconductor memory device according to a fifth embodiment.

### [Configuration]

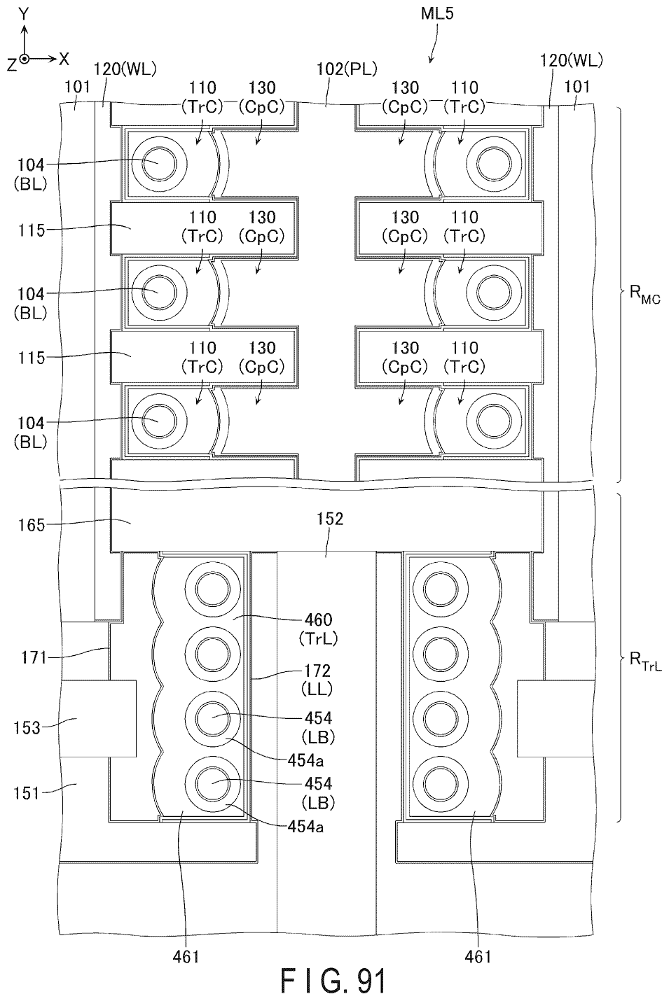

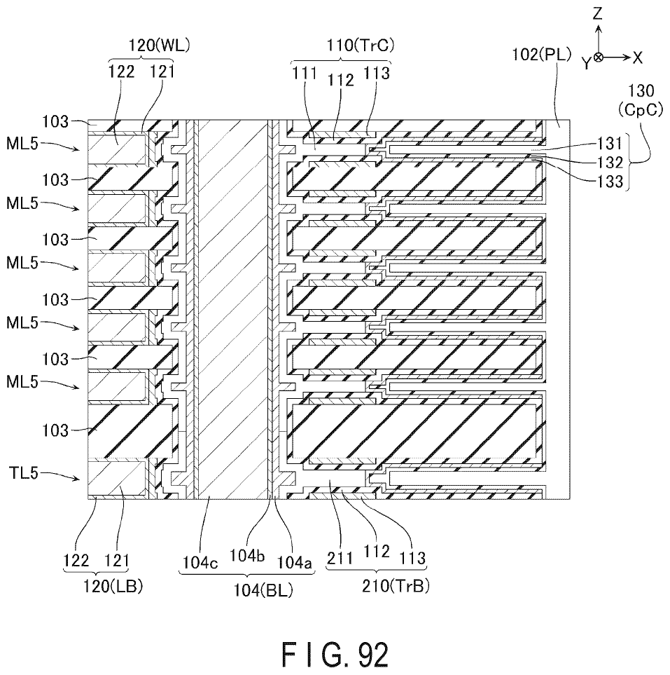

FIG. 91 and FIG. 92 are schematic cross-sectional views illustrating the configuration of a part of the semiconductor memory device according to the fifth embodiment. In the following description, the same numerals are assigned to elements similar to those in the second embodiment, and a description thereof is not repeated.

The semiconductor memory device according to the fifth embodiment is formed basically similarly to the semiconductor memory device according to the second embodiment.

However, the semiconductor memory device according to the fifth embodiment includes via wirings 454, memory layers ML5, and a transistor layer TL5, instead of the via wirings 154, the memory layers ML, and the transistor layer TL2.

The memory layers ML5 and the transistor layer TL5 are formed basically similarly to the memory layers ML and the transistor layer TL2. However, each of the memory layers ML5 and the transistor layer TL5 includes the transistor structure 460 instead of the transistor structure 160.

Note that, in the fifth embodiment, the wiring 171 includes silicon (Si) as the main component, and contains an N-type impurity such as phosphorus (P) or arsenic (As).

Also in the fifth embodiment, the threshold voltage of the transistor TrL (see FIG. 1) is lower than the threshold voltage of the transistor TrC.

### Sixth Embodiment

In the first embodiment to the fifth embodiment, the examples have been mainly illustrated in which the transistor TrL is an N-channel field effect transistor. However, such a configuration is merely exemplification, and the specific configuration can be appropriately adjusted. For example, it is also possible to form the transistor TrL as a P-channel field effect transistor. Hereinafter, such a configuration is exemplified as a semiconductor memory device according to a sixth embodiment.

### [Configuration]

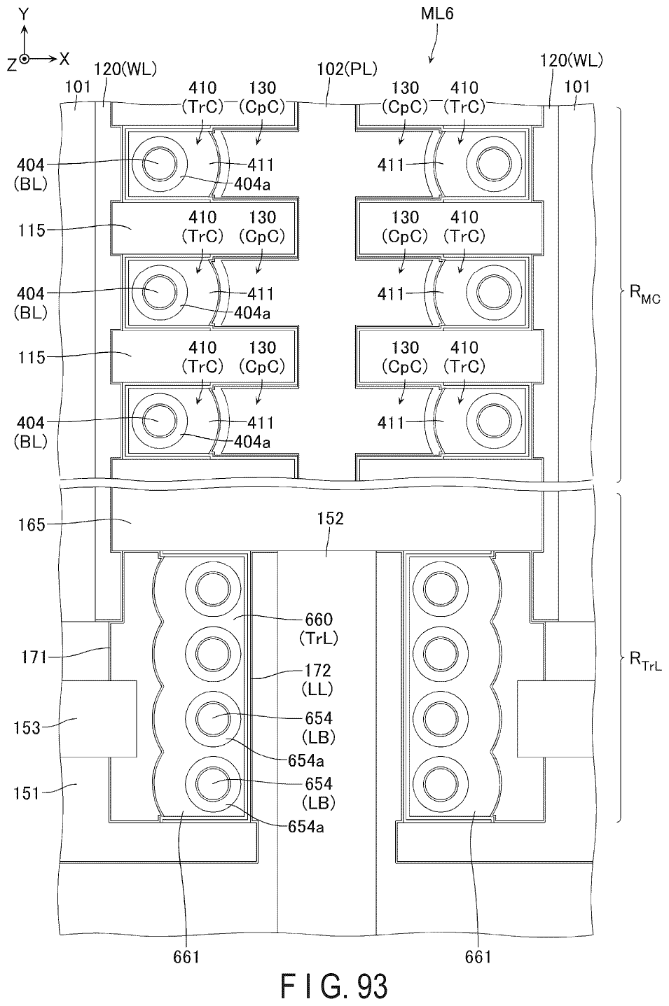

FIG. 93 is a schematic cross-sectional view illustrating the configuration of a part of the semiconductor memory device according to the sixth embodiment. In the following description, the same numerals are assigned to elements similar to those in the fourth embodiment, and a description thereof is not repeated.

The semiconductor memory device according to the sixth embodiment is formed basically similarly to the semiconductor memory device according to the fourth embodiment.

However, the semiconductor memory device according to the sixth embodiment includes via wirings 654, memory layers ML6, and a transistor layer TL6, instead of the via wirings 454, the memory layers ML4, and the transistor layer TL4.

The via wiring 654 is formed basically similarly to the via wiring 454. However, the via wiring 654 includes a semiconductor film 654a instead of the semiconductor film 454a (see FIG. 89). The semiconductor film 654a is formed basically similarly to the semiconductor film 454a. However, the semiconductor film 654a contains not an N-type impurity, but a P-type impurity such as boron (B).

The memory layers ML6 and the transistor layer TL6 are formed basically similarly to the memory layers ML4 and the transistor layer TL4. However, each of the memory layers ML6 and the transistor layer TL6 includes a transistor structure 660 instead of the transistor structure 460.

The transistor structure 660 is formed basically similarly to the transistor structure 460. However, the transistor structure 660 includes a semiconductor layer 661 instead of the semiconductor layer 461.

The semiconductor layer 661 is formed basically similarly to the semiconductor layer 461. However, the semiconductor layer 661 includes silicon (Si) as the main component, and contains an N-type impurity such as phosphorus (P) or arsenic (As).

Note that, in the sixth embodiment, the wiring 171 includes silicon (Si) as the main component, and contains a P-type impurity such as boron (B).

### Seventh Embodiment

In the first embodiment to the sixth embodiment, the bit lines BL are realized by the via wirings 104 extending in the Z direction, and the word lines WL are realized by the plurality of conductive layers 120 arranged in the Z direction. However, such a configuration is merely exemplification, and the specific configuration can be appropriately adjusted. For example, the word lines WL may be realized by via wirings or via electrodes extending in the Z direction, and the bit lines BL may be realized by a plurality of conductive layers arranged in the Z direction. Hereinafter, such a configuration is exemplified as a semiconductor memory device according to a seventh embodiment.

### [Circuit Configuration]

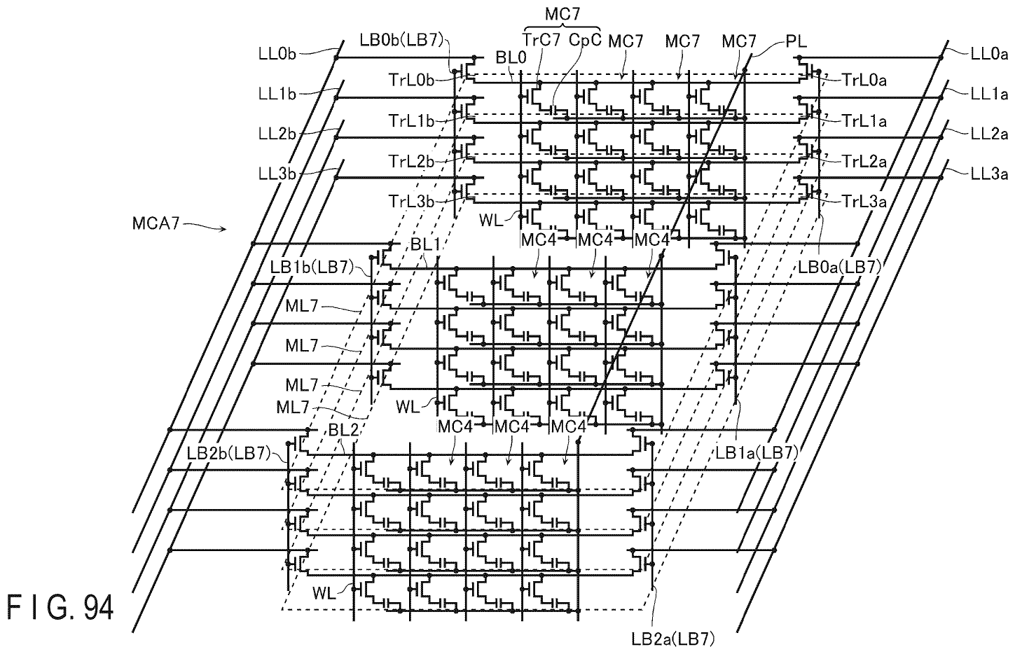

FIG. 94 is a schematic circuit diagram illustrating the configuration of a part of the semiconductor memory device according to the seventh embodiment. In the following description, the same numerals are assigned to elements similar to those in the first embodiment, and a description thereof is not repeated.

The semiconductor memory device according to the seventh embodiment includes a memory cell array MCA7. The memory cell array MCA7 includes a plurality of memory layers ML7, the plurality of word lines WL connected to these plurality of memory layers ML7, and the plate line PL connected to the plurality of memory layers ML7.

Each of the memory layers ML7 includes a plurality of bit lines BL0 to BL2 (hereinafter may be referred to as a “bit lines BL”), and a plurality of memory cells MC7 connected to these plurality of bit lines BL. Each of the memory cells MC7 includes a transistor TrC7 and a capacitor CpC. One electrode of the transistor TrC7 is connected to the bit line BL. The other electrode of the transistor TrC7 is connected to the capacitor CpC. Note that the one electrode and the other electrode of the transistor TrC7 function as a source electrode or a drain electrode according to the voltage applied to the transistor TrC7. A gate electrode of the transistor TrC7 is connected to the word line WL. One electrode of the capacitor CpC is connected to the drain electrode of the transistor TrC7. The other electrode of the capacitor CpC is connected to the plate line PL.

Note that each word line WL is connected to the plurality of memory cells MC7 corresponding to the plurality of memory layers ML7.

Additionally, one of the memory layers ML7 includes a plurality of transistors TrL0a and TrL0b, TrL1a and TrL1b, TrL2a and TrL2b, or TrL3a and TrL3b provided corresponding to each of the plurality of bit lines BL0 to BL2. One electrode of each transistor TrL is connected to any of the bit lines BL0 to BL2. The other electrode of the transistor TrL is connected to layer selection lines LL0a, LL0b, LL1a, LL1b, LL2a, LL2b, LL3a, or LL3b. Note that the one electrode and the other electrode of each transistor TrL function as a source electrode or a drain electrode according to the voltage applied to the transistors TrL. The gate electrode of each transistor TrL is connected to bit line selection line LB0a, LB0b, LB1a, LB1b, LB2a, or LB2b (hereinafter may be referred to as “bit line selection lines LB7”), respectively.

Note that the bit line selection lines LB7 are connected to the plurality of transistors TrL corresponding to the plurality of memory layers ML7. Additionally, each of the layer selection lines LL0a, LL1a, LL2a, and LL3a is commonly connected to all the transistors TrL0a, TrL1a, TrL2a, or TrL3a of the corresponding memory layer ML7. Similarly, each of the layer selection lines LL0b, LL1b, LL2b, and LL3b is commonly connected to all the transistors TrL0b, TrL1b, TrL2b, or TrL3b of the corresponding memory layer ML7.

### [Structure]

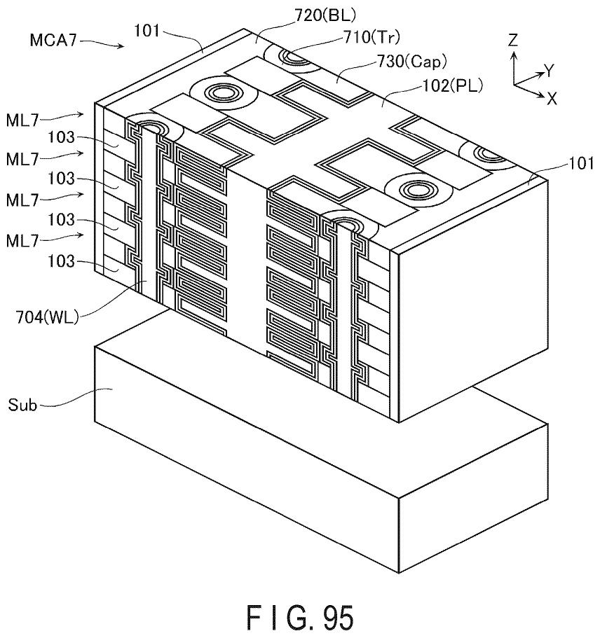

FIG. 95 is a schematic perspective view illustrating the configuration of a part of the semiconductor memory device according to the present embodiment. FIG. 95 illustrates a part of the semiconductor substrate Sub, and the memory cell array MCA7 provided above the semiconductor substrate Sub.

The memory cell array MCA7 includes the plurality of memory layers ML7 stacked in the Z direction. Additionally, the insulating layer 103 made from silicon oxide (SiO₂) or the like is provided in each of spaces between the plurality of memory layers ML7.

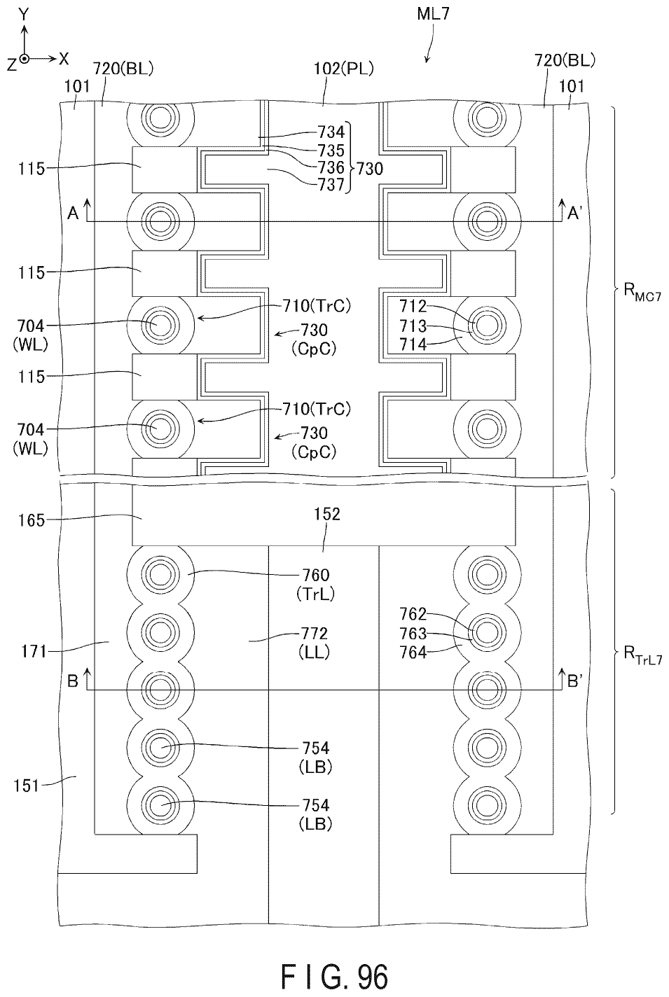

FIG. 96 is a schematic XY cross-sectional view illustrating the configuration of a part of the memory layer ML7. As illustrated in FIG. 96, the memory layer ML7 is provided with a memory cell area RMC7 and a transistor area RTrL7. Although illustration is omitted, transistor areas RTrL7 are provided on both sides of the memory cell area RMC7 in the Y direction.

### [Structure of Memory Cell Area RMC7]

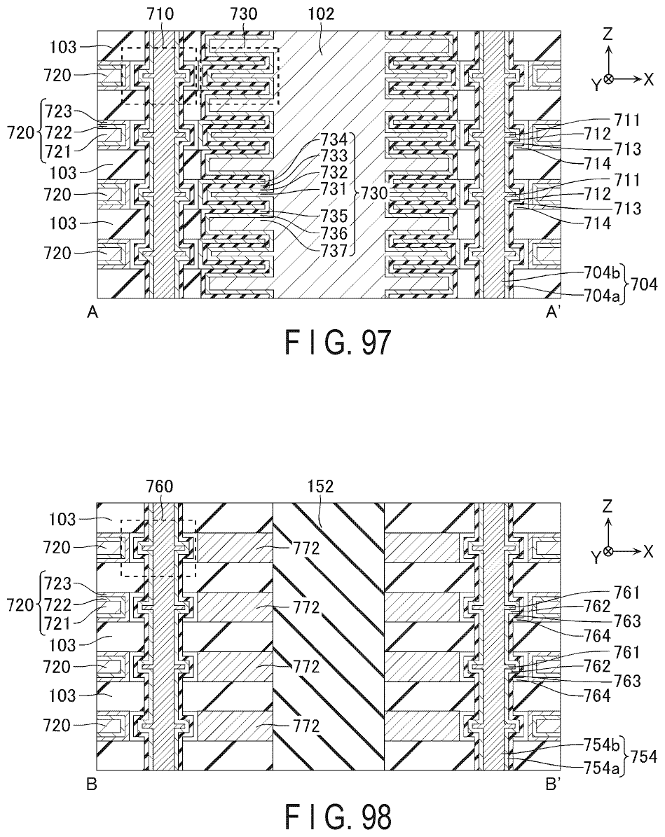

Next, the structure of the memory cell area RMC7 will be described with reference to FIG. 97 in addition to FIG. 95 and FIG. 96. FIG. 97 illustrates a cross section of the structure illustrated in FIG. 96 taken along A-A′ line.

As illustrated in FIG. 96, the memory cell area RMC7 includes the plurality of insulating layers 101 arranged in the X direction, and the conductive layer 102 provided between two insulating layers 101 that are adjacent to each other in the X direction. The insulating layers 101 and the conductive layer 102 extend in the Y direction and the Z direction, and divide the plurality of memory layers ML7 in the X direction (see FIG. 95).

A plurality of via electrodes 704 are provided in an area between the insulating layer 101 and the conductive layer 102. The plurality of via electrodes 704 are arranged in the Y direction, and as illustrated in, for example, FIG. 95, extend in the Z direction through the plurality of memory layers ML7.

As illustrated in FIG. 97, the via electrode 704 includes, for example, a barrier conductive film 704a made from titanium nitride (TiN) or the like, and a conductive member 704b made from tungsten (W) or the like.

The conductive member 704b has a substantially columnar shape extending in the Z direction. The barrier conductive film 704a has a substantially cylindrical shape extending in the Z direction along the outer peripheral surface of the conductive member 704b.

The via electrodes 704 function as, for example, the word lines WL (see FIG. 94). As illustrated in, for example, FIG. 94, the plurality of word lines WL are provided corresponding to the plurality of transistors TrC7 included in the memory layers ML7.

The memory layer ML7 includes a plurality of transistor structures 710 provided corresponding to the plurality of via electrodes 704, a conductive layer 720 provided on the opposite side of the conductive layer 102 with respect to the plurality of transistor structures 710, and a plurality of capacitor structures 730 provided between the plurality of transistor structures 710 and the conductive layer 102.

The transistor structure 710 includes: a substantially disk-shaped conductive layer 711 continuous with the conductive member 704b; a barrier conductive film 712 continuous with the barrier conductive film 704a, and provided on an upper surface, a lower surface, both side surfaces in the Y direction, and both side surfaces in the X direction of the conductive layer 711; an insulating layer 713 provided on an upper surface, a lower surface, both side surfaces in the Y direction, and both side surfaces in the X direction of the barrier conductive film 712; and a semiconductor layer 714 provided on an upper surface, a lower surface, both side surfaces in the Y direction, and both side surfaces in the X direction of the insulating layer 713.

In the XY cross-section as exemplified in FIG. 96, the side surfaces on both sides of the semiconductor layer 714 in the X direction may be formed along a circle centered on the center position of the via electrode 704. Additionally, the side surfaces on both sides of the semiconductor layer 714 in the Y direction may be formed in a straight line along the side surfaces of the insulating layers 115. Additionally, the outer peripheral surfaces of the barrier conductive film 712 and the insulating layer 713 may be formed along circles centered on the center position of the via electrode 704.

The conductive layer 711 and the barrier conductive film 712 function as, for example, a gate electrode of the transistor TrC7 (see FIG. 94). The conductive layer 711 includes, for example, a conductive member made from tungsten (W) or the like. The barrier conductive film 712 contains, for example, titanium nitride (TiN) or the like.

The insulating layer 713 functions as, for example, a gate insulating film of the transistor TrC7 (see FIG. 94). The insulating layer 713 contains, for example, silicon oxide (SiO₂) or the like.

The semiconductor layer 714 functions as, for example, a channel area of the transistor TrC7 (see FIG. 94). The semiconductor layer 714 may be, for example, a semiconductor containing at least one element of gallium (Ga) and aluminum (Al), indium (In), zinc (Zn), and oxygen (O), or may be other oxide semiconductor. A plurality of semiconductor layers 714 arranged in the Y direction are commonly connected to the conductive layer 720 extending in the Y direction. The semiconductor layer 714 faces the upper surface, the lower surface, both side surfaces in the Y direction, and both side surfaces in the X direction of the barrier conductive film 712 via the insulating layer 713.

The insulating layer 115 made from silicon oxide (SiO₂) or the like is provided between two semiconductor layers 714 that are adjacent to each other in the Y direction. The insulating layer 115 extends in the Z direction through the plurality of memory layers ML7.

The conductive layer 720 functions as, for example, the bit line BL (see FIG. 94). The conductive layer 720 extends in the Y direction, and is connected to the plurality of semiconductor layers 714 arranged in the Y direction. The conductive layer 720 includes, for example, a conductive oxide film 723 containing a conductive oxide, a barrier conductive film 722 made from titanium nitride (TiN) or the like, and a conductive film 721 made from tungsten (W). Note that, instead of the conductive oxide film 723, the conductive layer 720 may contain ruthenium (Ru), iridium (Ir), or other metals. Additionally, the conductive layer 720 may contain only the conductive oxide, or may contain only ruthenium (Ru), iridium (Ir), or other metals.

As illustrated in, for example, FIG. 97, the capacitor structure 730 includes a conductive layer 731, a barrier conductive film 732 provided on an upper surface, a lower surface, both side surfaces in the Y direction, and a side surface on the transistor structure 710 side in the X direction of the conductive layer 731, an insulating layer 733 provided on an upper surface, a lower surface, both side surfaces in the Y direction, and a side surface on the transistor structure 710 side in the X direction of the barrier conductive film 732, a conductive layer 734 provided on an upper surface, a lower surface, both side surfaces in the Y direction, and a side surface on the transistor structure 710 side in the X direction of the insulating layer 733, an insulating layer 735 provided on an upper surface, a lower surface, and both side surfaces in the Y direction of the conductive layer 734, and a side surface in the X direction of the insulating layer 103, a barrier conductive film 736 provided on an upper surface, a lower surface, both side surfaces in the Y direction of the insulating layer 735, and the side surface in the X direction of the insulating layer 103, and a conductive layer 737 provided on an upper surface, a lower surface, both side surfaces in the Y direction, and a side surface on the transistor structure 710 side in the X direction of the barrier conductive film 736.

The conductive layers 731 and 737 and the barrier conductive films 732 and 736 function as one electrode of the capacitor CpC (see FIG. 94). The conductive layers 731 and 737 include, for example, a conductive member made from tungsten (W) or the like. The barrier conductive films 732 and 736 contain, for example, titanium nitride (TiN) or the like. The conductive layers 731 and 737 and the barrier conductive films 732 and 736 are continuous with the conductive layer 102.

The insulating layers 733 and 735 function as an insulating layer of the capacitor CpC (see FIG. 94). The insulating layers 733 and 735 may be, for example, zirconia (ZrO2), alumina (Al₂O₃), or other insulating metal oxides. Additionally, the insulating layers 733 and 735 may be, for example, a stacked film of a plurality of insulating metal oxides (for example, a stacked film of zirconia and alumina).

The conductive layer 734 functions as, for example, the other electrode of the capacitor CpC (see FIG. 94). The conductive layer 734 contains, for example, a conductive oxide such as indium tin oxide (ITO). The conductive layer 734 is insulated from the barrier conductive films 732 and 736 via the insulating layers 733 and 735. The conductive layer 734 is connected to a side surface of the semiconductor layer 714 in the X direction.

### [Structure of Transistor Area RTrL7]

Next, the structure of transistor area RTrL7 will be described with reference to FIG. 98 in addition to FIG. 95 and FIG. 96. FIG. 98 illustrates a cross section of the structure illustrated in FIG. 96 taken along B-B′ line.

As illustrated in FIG. 96, the transistor area RTrL7 includes the plurality of insulating layers 151 arranged in the X direction corresponding to the plurality of insulating layers 101, and the insulating layer 152 provided between two insulating layers 151 that are adjacent to each other in the X direction.

Additionally, the insulating layer 165 extending in the X direction in the range between two conductive layers 720 that are adjacent to each other in the X direction is provided between the memory cell area RMC7 and the transistor area RTrL7.

A plurality of via electrodes 754 are provided in an area between the insulating layer 151 and the insulating layer 152. The plurality of via electrodes 754 are arranged in the Y direction, and extend in the Z direction through the plurality of memory layers ML7 as illustrated in, for example, FIG. 98.

As illustrated in FIG. 98, the via electrode 754 includes, for example, a barrier conductive film 754a made from titanium nitride (TiN) or the like, and a conductive member 754b made from tungsten (W) or the like.

The conductive member 754b has a substantially columnar shape extending in the Z direction. The barrier conductive film 754a has a substantially cylindrical shape extending in the Z direction along the outer peripheral surface of the conductive member 754b.

The plurality of via electrodes 754 arranged in the Y direction function as, for example, one bit line selection line LB7 (see FIG. 94). A plurality of bit line selection lines LB7 are provided corresponding to the plurality of bit lines BL included in the memory layer ML7 as illustrated in, for example, FIG. 94.

The memory layer ML7 includes a plurality of transistor structures 760 provided corresponding to the plurality of conductive layers 720, the wiring 171 provided between the transistor structure 760 and the insulating layer 151, and a wiring 772 provided between the transistor structure 760 and the insulating layer 152.

The transistor structure 760 includes: a conductive layer 761 continuous with the outer peripheral surface of the plurality of via electrodes 754; a barrier conductive film 762 provided on an upper surface, a lower surface, both side surfaces in the Y direction, and both side surfaces in the X direction of the conductive layer 761; an insulating layer 763 provided on an upper surface, a lower surface, both side surfaces in the Y direction, and both side surfaces in the X direction of the barrier conductive film 762; and a semiconductor layer 764 provided on an upper surface, a lower surface, both side surfaces in the Y direction, and both side surfaces in the X direction of the insulating layer 763.

In an XY cross-section as exemplified in FIG. 96, the side surfaces on both sides of the semiconductor layer 764 in the X direction may be formed along a plurality of circles that are centered on the plurality of center positions of the plurality of via electrodes 754 and that overlap with each other. Additionally, the outer peripheral surfaces of the barrier conductive film 762 and the insulating layer 763 may be formed along a plurality of circles that are centered on the plurality of center positions of the plurality of via electrodes 754 and that are separated from each other.

The conductive layer 761 and the barrier conductive film 762 function as, for example, a gate electrode of the transistor TrL7 (see FIG. 94). The conductive layer 761 includes, for example, a conductive member made from tungsten (W) or the like. The barrier conductive film 762 contains, for example, titanium nitride (TiN) or the like.

The insulating layer 763 functions as, for example, a gate insulating film of the transistor TrL7. The insulating layer 763 contains, for example, a silicon oxide (SiO₂) or the like.

The semiconductor layer 764 functions as, for example, a channel area of the transistor TrL7. The semiconductor layer 764 may be, for example, a semiconductor containing at least one element of gallium (Ga) and aluminum (Al), indium (In), zinc (Zn), and oxygen (O), or may be other oxide semiconductor. The semiconductor layer 764 is electrically connected to the wirings 171 and 772.

Here, the concentration of indium in the semiconductor layer 764 is higher than the concentration of indium in the semiconductor layer 714. Additionally, the concentration of gallium in the semiconductor layer 764 is equal to or less than the concentration of gallium in the semiconductor layer 714. Accordingly, the threshold voltage of the transistor TrL becomes lower than the threshold voltage of transistor TrC7.

As illustrated in FIG. 96, the wiring 772 includes a portion extending in the Y direction, and a portion extending in the X direction. The portion of the wiring 772 extending in the Y direction is connected to the semiconductor layer 764. The wiring 772 has a function of connecting the source electrode of the transistor TrL (see FIG. 94) to the control circuit. The wiring 772 contains, for example, a conductive oxide. Note that, instead of the conductive oxide, the wiring 772 may contain ruthenium (Ru), iridium (Ir), or other metals. Additionally, the wiring 772 may contain only the conductive oxide, or may contain only ruthenium (Ru), iridium (Ir), or other metals.

### Other Embodiments

The semiconductor memory devices according to the first embodiment to the seventh embodiment have been described above. However, the semiconductor memory devices according to these embodiments are merely exemplification, and the specific configuration and the like can be appropriately adjusted.

For example, in the semiconductor memory devices according to the fourth embodiment to the sixth embodiment, the concentration of the P-type impurity in the semiconductor layers 411 and 111 in the transistor layers TL4, TL5, and TL6 may be set lower than the concentration of the P-type impurity in the semiconductor layers 411 and 111 in the memory layers ML4, ML5, and ML6. Accordingly, the threshold voltage of the transistor TrB (see FIG. 1) may be set lower than the threshold voltage of the transistor TrC.

Additionally, for example, in the semiconductor memory devices according to the second embodiment to the fourth embodiment, it is also possible to adjust only the threshold voltage of the transistor TrB (see FIG. 1), and not the threshold voltage of the transistor TrL. For example, in the second embodiment and the third embodiment, the concentration of indium and the concentration of gallium in the semiconductor layers 161 and 361 may be set equal to the concentration of indium and the concentration of gallium in the semiconductor layer 111, respectively. Additionally, in the fourth embodiment, the concentration of the P-type impurity in the semiconductor layer 461 may be set equal to the concentration of the P-type impurity in the semiconductor layer 411.

Additionally, for example, when manufacturing the semiconductor memory device according to the fourth embodiment, it is also possible to collectively deposit the semiconductor layers 411 and 461 with the method as exemplified in the third embodiment. In this case, the areas RSL and RCL as described with reference to FIG. 85 may be provided in the semiconductor layer 461, and the concentration of the P-type impurity in the area RCL may become lower than the concentration of the P-type impurity in the area RSL.

Additionally, for example, when manufacturing the semiconductor memory device according to any of the embodiments, the region RCL may contain a different material from the region RSL with the method as exemplified in the third embodiment. Similarly, the area RCB may contain a different material from the area RSB.

Additionally, for example, in the semiconductor memory device according to the seventh embodiment, the semiconductor layers 714 and 764 may include silicon (Si) as the main component, and may contain a P-type impurity such as boron (B). In this case, the concentration of the P-type impurity in the semiconductor layer 764 may be lower than the concentration of the P-type impurity in the semiconductor layer 714. Additionally, the semiconductor layer 764 may contain a different material from the semiconductor layer 714.

Additionally, in the semiconductor memory devices according to the first embodiment to the third embodiment, the via wirings 104, 154, and the like that function as the bit lines contain the conductive oxide such as indium tin oxide (ITO). However, such a conductive oxide may be contained in the transistor structures 110, 160, and the like, instead of the via wirings 104, 154, and the like extending in the Z direction. Additionally, the via wirings 104, 154, and the like and the transistor structures 110 and 160 may include other materials and the like.

Additionally, in the semiconductor memory devices according to the fourth embodiment and the sixth embodiment, the via wirings 404, 454, and the like that function as the bit lines include the semiconductor films 404a, 454a, and the like. However, such semiconductor films 404a, 454a, and the like may be included in the transistor structures 410, 460, and the like, instead of the via wirings 404, 454, and the like extending in the Z direction. Additionally, the via wirings 404, 454, and the like and the transistor structures 410 and 460 may include other materials and the like.

Additionally, in the semiconductor memory devices according to the first embodiment to the sixth embodiment, the conductive layer 113 that functions as the gate electrode of the transistor TrC may face only one of the upper surface and the lower surface of the semiconductor layer 111 that functions as the channel area of the transistor TrC.

Additionally, in the above description, a description has been given of the example in which the capacitor CpC is adopted as the memory unit connected to the transistor structure 110. However, the memory unit may not be the capacitor CpC. For example, the memory unit may include a ferroelectric, a ferromagnetic, a chalcogen material such as GeSbTe, or other materials, and may record data by utilizing the characteristics of these materials. For example, in any of the structures described above, any of these materials may be included in the insulating layer between the electrodes that form the capacitor CpC.

Additionally, the manufacturing methods of the semiconductor memory devices according to the first embodiment to the sixth embodiment can also be appropriately adjusted. For example, the order of any two of the aforementioned steps may be replaced, or any two of the aforementioned steps may be performed at the same time.

### Others

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor memory device, comprising:
a substrate;
a plurality of first semiconductor layers stacked in a first direction intersecting a surface of the substrate;
a first via wiring extending in the first direction and electrically connected to the plurality of first semiconductor layers;
a plurality of memory units stacked in the first direction and electrically connected to the plurality of first semiconductor layers;
a plurality of first gate electrodes stacked in the first direction and facing the plurality of first semiconductor layers;
a plurality of first wirings stacked in the first direction, extending in a second direction intersecting the first direction, and electrically connected to the plurality of first gate electrodes;
a plurality of second semiconductor layers stacked in the first direction and electrically connected to the plurality of first gate electrodes via the plurality of first wirings;
a second via wiring extending in the first direction and electrically connected to the plurality of second semiconductor layers; and
a plurality of second gate electrodes stacked in the first direction and facing the plurality of second semiconductor layers, wherein
the plurality of second semiconductor layers include a material that is different from any material included in the plurality of first semiconductor layers, or a composition ratio of materials included in the plurality of second semiconductor layers is different from a composition ratio of materials included in the plurality of first semiconductor layers.

2. The semiconductor memory device according to claim 1, wherein
each of the first and second semiconductor layers includes: at least one of gallium and aluminum, indium, zinc, and oxygen, and
a concentration of indium in the second semiconductor layers is higher than a concentration of indium in the first semiconductor layers.

3. The semiconductor memory device according to claim 1, wherein each of the first and second semiconductor layers includes silicon as a main component.

4. The semiconductor memory device according to claim 3, wherein
each of the first and second semiconductor layers includes a P-type impurity, and
a concentration of the P-type impurity in the second semiconductor layers is lower than a concentration of the P-type impurity in the first semiconductor layers.

5. The semiconductor memory device according to claim 3, wherein
the first semiconductor layers include a P-type impurity, and
the second semiconductor layers include an N-type impurity.

6. The semiconductor memory device according to claim 1, wherein a length of the second semiconductor layers in the first direction is larger than a length of the first semiconductor layers in the first direction.

7. The semiconductor memory device according to claim 1, wherein
each of the second semiconductor layers includes:
a first area and a second area that are arranged in the first direction, and
a third area between the first and second areas, and
the third area includes a material that is different from any material included in the first and second areas, or a composition ratio of materials included in the third area is different from a composition ratio of materials included in the first and second areas.

8. The semiconductor memory device according to claim 1, further comprising:
a second wiring on one side of the plurality of first semiconductor layers in the first direction, the second wiring extending in a third direction intersecting the first and second directions;
a third semiconductor layer provided between the plurality of first semiconductor layers and the second wiring and electrically connected to the first via wiring and the second wiring; and
a third gate electrode facing the third semiconductor layer, wherein
the third semiconductor layer includes a material that is different from any material included in the plurality of first semiconductor layers, or a composition ratio of materials included in the third semiconductor layer is different from a composition ratio of materials included in the plurality of first semiconductor layers.

9. The semiconductor memory device according to claim 1, wherein the memory units are capacitors.

10. The semiconductor memory device according to claim 1, wherein
each of the first gate electrodes either faces one of the first semiconductor layers that is adjacent to said each of the first gate electrodes or is between two of the first semiconductor layers that are adjacent to each other in the first direction,
the memory units are on one side of the first semiconductor layers in a third direction intersecting the first and second directions, and
the first wirings are on the other side of the first semiconductor layers in the third direction.

11. A semiconductor memory device, comprising:
a substrate;
a plurality of semiconductor layers stacked in a first direction intersecting a surface of the substrate;
a via wiring extending in the first direction and electrically connected to the plurality of semiconductor layers;
a plurality of memory units stacked in the first direction and electrically connected to the plurality of semiconductor layers;
a plurality of gate electrodes stacked in the first direction and facing the plurality of semiconductor layers;
a plurality of first wirings stacked in the first direction, extending in a second direction intersecting the first direction, and electrically connected to the plurality of gate electrodes;
a second wiring provided on one side of the plurality of semiconductor layers in the first direction and extending in a third direction intersecting the first and second directions;
another semiconductor layer provided between the plurality of semiconductor layers and the second wiring and electrically connected to the via wiring and the second wiring; and
another gate electrode facing said another semiconductor layer, wherein
said another semiconductor layer includes a material that is different from any material included in the plurality of semiconductor layers, or a composition ratio of materials included in said another semiconductor layer is different from a composition ratio of materials included in the plurality of semiconductor layers.

12. The semiconductor memory device according to claim 11, wherein
each of the semiconductor layers and said another semiconductor layer include at least one of gallium and aluminum, indium, zinc, and oxygen, and
a concentration of indium in said another semiconductor layer is higher than a concentration of indium in the semiconductor layers.

13. The semiconductor memory device according to claim 11, wherein each of the semiconductor layers and said another semiconductor layer include silicon as a main component.

14. The semiconductor memory device according to claim 13, wherein
each of the semiconductor layers and said another semiconductor layer includes a P-type impurity, and
a concentration of the P-type impurity in said another semiconductor layer is lower than a concentration of the P-type impurity in the semiconductor layers.

15. The semiconductor memory device according to claim 13, wherein
the semiconductor layers include a P-type impurity, and
said another semiconductor layer includes an N-type impurity.

16. The semiconductor memory device according to claim 11, wherein a length of said another semiconductor layer in the first direction is larger than a length of the semiconductor layers in the first direction.

17. The semiconductor memory device according to claim 11, wherein
said another semiconductor layer includes:
a first area and a second area that are arranged in the first direction, and
a third area between the first and second areas, and
the third area includes a material that is different from any material included in the first and second areas, or a composition ratio of materials included in the third area is different from a composition ratio of materials included in the first and second areas.

18. The semiconductor memory device according to claim 11, wherein the memory units are capacitors.

19. The semiconductor memory device according to claim 11, wherein
each of the gate electrodes faces either faces one of the semiconductor layers that is adjacent to said each of the gate electrodes or is between two of the semiconductor layers that are adjacent to each other in the first direction,
the memory units are on one side of the semiconductor layers in the third direction, and
the first wirings are on the other side of the semiconductor layers in the third direction.

20. A semiconductor memory device, comprising:
a substrate;
a plurality of first semiconductor layers stacked in a first direction intersecting a surface of the substrate;
a first via electrode extending in the first direction and facing the plurality of first semiconductor layers;
a plurality of memory units stacked in the first direction and electrically connected to the plurality of first semiconductor layers;
a plurality of wirings stacked in the first direction, extending in a second direction intersecting the first direction, and electrically connected to the plurality of first semiconductor layers;
a plurality of second semiconductor layers stacked in the first direction and electrically connected to the plurality of first semiconductor layers via the plurality of wirings; and
a second via electrode extending in the first direction and facing the plurality of second semiconductor layers, wherein
the plurality of second semiconductor layers include a material that is different from any material included in the plurality of first semiconductor layers, or a composition ratio of materials included in the plurality of second semiconductor layers is different from a composition ratio of materials included in the plurality of first semiconductor layers.
